(19) United States
(12) Patent Application Publication
(10) Pub. No.: US 2026/0156918 A1
(43) Pub. Date: Jun. 4, 2026

(54) SEMICONDUCTOR DEVICE

(71) Applicants: Kabushiki Kaisha Toshiba, Kawasaki-shi (JP); Toshiba Electronic Devices & Storage Corporation, Kawasaki-shi (JP)

(72) Inventor: Kazutoshi NAKAMURA, Nonoichi Ishikawa (JP)

(21) Appl. No.: 19/368,737

(22) Filed: Oct. 24, 2025

(30) Foreign Application Priority Data
Dec. 4, 2024 (JP) 2024-211668

(51) Int. Cl. H10D 84/00; H10D 12/00

(52) U.S. Cl. CPC H10D 84/161; H10D 12/415; H10D 12/481

(57) ABSTRACT

A semiconductor device of an embodiment includes a transistor region, a diode region, and a termination region. The diode region includes trenches of a first group extending in a first direction and repeatedly arranged in a second direction, and the termination region includes the trenches. The trenches include a first trench, a second trench, a third trench, and a fourth trench, the first trench and the second trench are connected in the termination region, and the third trench and the fourth trench are connected in the termination region. The second trench and the third trench are adjacent in the second direction, and a first minimum distance in the second direction between the second trench and the third trench in the termination region is smaller than a second minimum distance in the second direction between the second trench and the third trench in the diode region.

### CROSS-REFERENCE TO RELATED APPLICATION

This application is based upon and claims the benefit of priority from Japanese Patent Application No. 2024-211668, filed on December 4, 2024, the entire contents of which are incorporated herein by reference.

### FIELD

Embodiments described herein relate generally to a semiconductor device.

### BACKGROUND

An insulated gate bipolar transistor (IGBT) is one example of a power semiconductor device. In the IGBT, for example, a p-type collector region, an n-type drift region, and a p-type base region are provided on a collector electrode. A gate electrode is provided in a trench penetrating through the p-type base region and reaching the n-type drift region, with a gate insulating film interposed between the gate electrode and the trench. An n-type emitter region connected to an emitter electrode is provided in a region adjacent to the trench on the surface of the p-type base region.

In recent years, a reverse-conducting IGBT (RC-IGBT) in which an IGBT and a free wheeling diode are formed in the same semiconductor chip has been widely developed and commercialized. The RC-IGBT is used, for example, as a switching element in an inverter circuit. The free wheeling diode has a function of making a current flow in a direction opposite to the on-current of the IGBT. Forming the IGBT and the free wheeling diode in the same semiconductor chip has many advantages, such as simplification of an assembly process and dispersion of heat generation locations.

Since the IGBT and the free wheeling diode are formed in the same semiconductor chip, the structure and process of the free wheeling diode cannot be necessarily optimized, and the characteristics of the free wheeling diode may deteriorate. It is desired to improve the characteristics of the free wheeling diode of the RC-IGBT.

### BRIEF DESCRIPTION OF THE DRAWINGS

FIG. 1 is a schematic diagram of a semiconductor device of a first embodiment;

FIG. 2 is a schematic cross-sectional view of a part of the semiconductor device of the first embodiment;

FIG. 3 is a schematic top view of a part of the semiconductor device of the first embodiment;

FIG. 4 is a schematic top view of a part of the semiconductor device of the first embodiment;

FIG. 5 is a schematic cross-sectional view of a part of the semiconductor device of the first embodiment;

FIG. 6 is a schematic top view of a part of the semiconductor device of the first embodiment;

FIG. 7 is a schematic top view of a part of the semiconductor device of the first embodiment;

FIG. 8 is a schematic cross-sectional view of a part of the semiconductor device of the first embodiment;

FIG. 9 is a schematic cross-sectional view of a part of the semiconductor device of the first embodiment;

FIG. 10 is a schematic cross-sectional view of a part of a semiconductor device of a comparative example;

FIG. 11 is an explanatory diagram of the function and effect of the semiconductor device of the first embodiment;

FIG. 12 is an explanatory diagram of the function and effect of the semiconductor device of the first embodiment;

FIG. 13 is an explanatory diagram of the function and effect of the semiconductor device of the first embodiment;

FIG. 14 is an explanatory diagram of the function and effect of the semiconductor device of the first embodiment;

FIG. 15 is an explanatory diagram of the function and effect of the semiconductor device of the first embodiment;

FIG. 16 is a schematic cross-sectional view of a part of a semiconductor device of a first modification of the first embodiment;

FIG. 17 is an explanatory diagram of the function and effect of the semiconductor device of the first modification of the first embodiment;

FIG. 18 is a schematic cross-sectional view of a part of a semiconductor device of a second modification of the first embodiment;

FIG. 19 is an explanatory diagram of the function and effect of the semiconductor device of the second modification of the first embodiment;

FIG. 20 is a schematic top view of a part of a semiconductor device of a second embodiment;

FIG. 21 is a schematic cross-sectional view of a part of the semiconductor device of the second embodiment; and

FIG. 22 is a schematic cross-sectional view of a part of the semiconductor device of the second embodiment.

### DETAILED DESCRIPTION

A semiconductor device of an embodiment includes: a transistor region; a diode region; and a termination region surrounding the transistor region and the diode region, wherein the diode region includes: a semiconductor layer having a first face and a second face opposed to the first face; a first semiconductor region of a first conductivity type provided in the semiconductor layer; a second semiconductor region of the first conductivity type provided in the semiconductor layer, provided between the first semiconductor region and the first face, and having a first conductivity type impurity concentration lower than a first conductivity type impurity concentration of the first semiconductor region; a third semiconductor region of a second conductivity type provided in the semiconductor layer and provided between the second semiconductor region and the first face; trenches of a first group provided on a side of the first face of the semiconductor layer, extending in a first direction parallel to the first face, arranged repeatedly in a second direction parallel to the first face and perpendicular to the first direction, and in contact with the second semiconductor region and the third semiconductor region; a first electrode electrically connected to the third semiconductor region; and a second electrode in contact with the first semiconductor region, the termination region includes: the semiconductor layer; the second semiconductor region; a fourth semiconductor region of the second conductivity type provided in the semiconductor layer, provided between the second semiconductor region and the first face, electrically connected to the first electrode, and having a depth deeper than a depth of the third semiconductor region; the trenches of the first group; and the second electrode, wherein the trenches of the first group include a first trench, a second trench, a third trench, and a fourth trench, the first trench and the second trench are physically connected in the termination region, the third trench and the fourth trench are physically connected in the termination region, the second trench and the third trench are adjacent to each other in the second direction, and a first minimum distance in the second direction between the second trench and the third trench in the termination region is smaller than a second minimum distance in the second direction between the second trench and the third trench in the diode region.

Hereinafter, embodiments of this disclosure will be described with reference to the drawings. Note that, in the following description, the same or similar members and the like are denoted by the same reference numerals, and the description of the members and the like once described will be omitted as appropriate.

In this specification, when there are notations of n⁺-type, n-type, and n⁻-type, it means that an n-type impurity concentration decreases in the order of n⁺-type, n-type, and n⁻-type. When there are notations of p⁺-type, p-type, and p⁻-type, it means that a p-type impurity concentration decreases in the order of p⁺-type, p-type, and p⁻-type.

In this specification, the n-type impurity concentration does not indicate an actual n-type impurity concentration, but indicates an effective n-type impurity concentration after compensation. Similarly, the p-type impurity concentration does not indicate an actual p-type impurity concentration, but indicates an effective p-type impurity concentration after compensation. For example, when the actual n-type impurity concentration is higher than the actual p-type impurity concentration, the concentration obtained by subtracting the p-type impurity concentration from the actual n-type impurity concentration is defined as the n-type impurity concentration. The same applies to the p-type impurity concentration.

In this specification, the distribution and absolute value of the impurity concentration of a semiconductor region can be measured using, for example, secondary ion mass spectrometry (SIMS). A relative magnitude relationship between the impurity concentrations of two semiconductor regions can be determined using, for example, scanning capacitance microscopy (SCM). The distribution and absolute value of the impurity concentration can be measured using, for example, spreading resistance analysis (SRA). In the SCM and the SRA, the relative magnitude relationship and absolute value of carrier concentration of the semiconductor region are obtained. By assuming an activation rate of the impurity, it is possible to obtain the relative magnitude relationship between the impurity concentrations of two semiconductor regions, the distribution of the impurity concentration, and the absolute value of the impurity concentration from the measurement results of the SCM and the SRA.

As for the impurity concentration of the semiconductor region, the impurity concentration is represented by the maximum concentration of the semiconductor region unless otherwise specified in the specification.

### First Embodiment

A semiconductor device of a first embodiment includes a transistor region, a diode region, and a termination region surrounding the transistor region and the diode region. The diode region includes: a semiconductor layer having a first face and a second face opposed to the first face; a first semiconductor region of a first conductivity type provided in the semiconductor layer; a second semiconductor region of a first conductivity type provided in the semiconductor layer, provided between the first semiconductor region and the first face, and having a first conductivity type impurity concentration lower than a first conductivity type impurity concentration of the first semiconductor region; a third semiconductor region of a second conductivity type provided in the semiconductor layer and provided between the second semiconductor region and the first face; trenches of a first group provided on a side of the first face of the semiconductor layer, extending in a first direction parallel to the first face, arranged repeatedly in a second direction parallel to the first face and perpendicular to the first direction, and in contact with the second semiconductor region and the third semiconductor region; a first electrode electrically connected to the third semiconductor region; and a second electrode in contact with the first semiconductor region. The termination region includes: the semiconductor layer; the second semiconductor region; a fourth semiconductor region of a second conductivity type provided in the semiconductor layer, provided between the second semiconductor region and the first face, electrically connected to the first electrode, and having a depth deeper than a depth of the third semiconductor region; the trenches of the first group; and the second electrode. The trenches of the first group include a first trench, a second trench, a third trench, and a fourth trench. The first trench and the second trench are physically connected in the termination region, the third trench and the fourth trench are physically connected in the termination region, and the second trench and the third trench are adjacent to each other in the second direction. A first minimum distance in the second direction between the second trench and the third trench in the termination region is smaller than a second minimum distance in the second direction between the second trench and the third trench in the diode region.

The semiconductor device of the first embodiment is an RC-IGBT 100 in which an IGBT and a free wheeling diode are formed on the same semiconductor chip. The RC-IGBT 100 includes a trench-gate type IGBT including a gate electrode in a trench formed in a semiconductor layer. Hereinafter, a case where a first conductivity type is n-type and a second conductivity type is p-type will be described as an example.

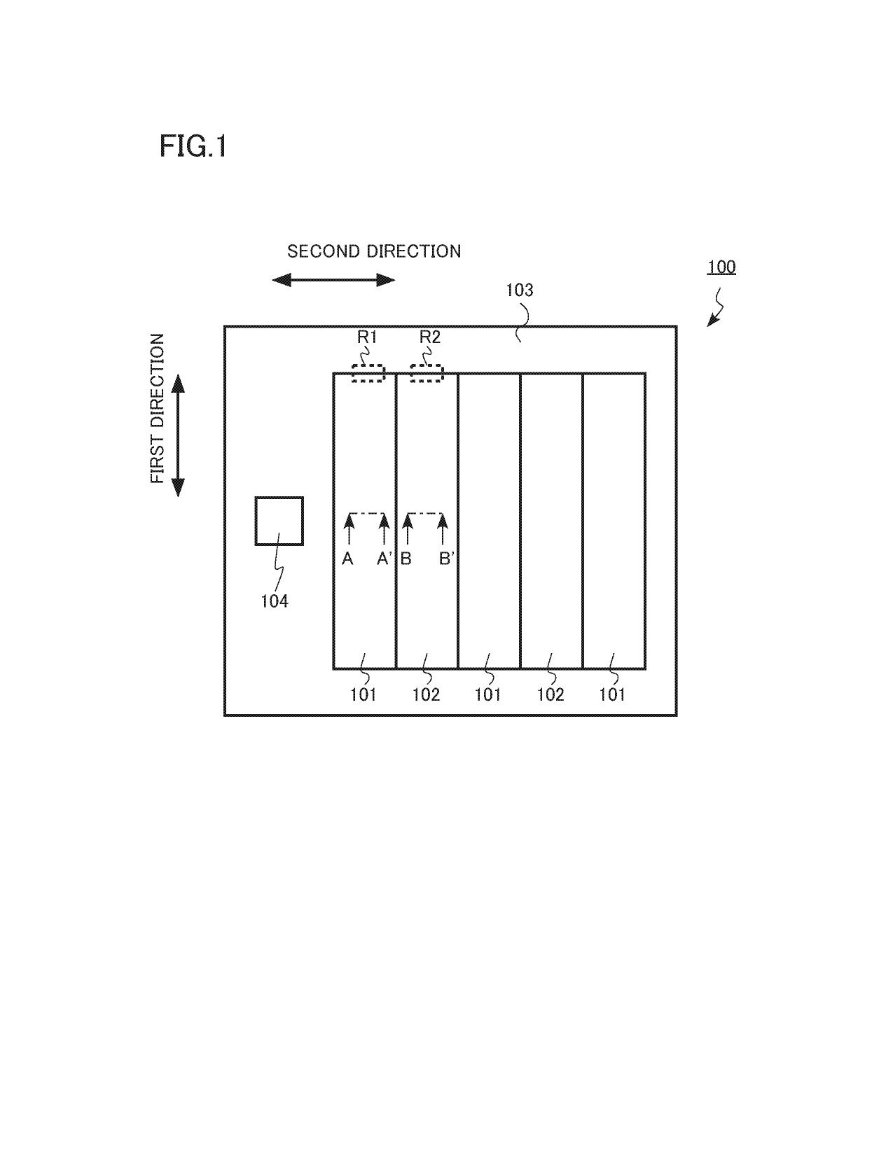

FIG. 1 is a schematic diagram of a semiconductor device of a first embodiment.

As illustrated in FIG. 1, the RC-IGBT 100 includes a transistor region 101, a diode region 102, and a termination region 103. The transistor region 101 and the diode region 102 are alternately disposed in the second direction perpendicular to the first direction. The termination region 103 surrounds the transistor region 101 and the diode region 102.

The transistor region 101 operates as the IGBT. The diode region 102 operates as the free wheeling diode. The free wheeling diode is, for example, a fast recovery diode (FRD).

The termination region 103 lessens the intensity of the electric field applied to the termination portion of the pn junction in the transistor region 101 and the diode region 102 when the RC-IGBT 100 is in an off-state. The termination region 103 has a function of improving a breakdown voltage of the RC-IGBT 100.

A gate electrode pad 104 is provided in the termination region 103. Specifically, the gate electrode pad is provided above a diffusion layer of a p-type guard ring region 34 described later with an insulating film interposed between the gate electrode pad and the diffusion layer.

The RC-IGBT 100 of the first embodiment includes a semiconductor layer 10, an upper electrode 12 (first electrode), a lower electrode 14 (second electrode), a gate insulating film 41, a dummy gate insulating film 42, a trench insulating film 43, a gate electrode 51, a dummy gate electrode 52, a conductive layer 53, an interlayer insulating layer 60, and a gate electrode pad 104.

In the semiconductor layer 10, trenches 21 of a first group, trenches 22 of a second group, a p⁺-type collector region 26 (sixth semiconductor region), an n⁻-type drift region 27 (second semiconductor region), a p-type cell base region 28 (seventh semiconductor region), an n⁺-type cell emitter region 29 (eighth semiconductor region), a p⁺-type cell contact region 30, an n⁺-type cathode region 31 (first semiconductor region), a p-type anode region 32 (third semiconductor region), a p⁺-type diode contact region 33, a p-type guard ring region 34 (fourth semiconductor region), and a p⁺-type termination back surface p region 35 (fifth semiconductor region) are provided.

The trenches 21 of the first group include an A trench 21a, a B trench 21b, a C trench 21c, a D trench 21d, an E trench 21e, an F trench 21f, a G trench 21g, an H trench 21h, an I trench 21i, and a J trench 21j.

The trenches 22 of the second group include gate trenches 22x and dummy gate trenches 22y.

In this specification, the “trench” means a groove provided in the semiconductor layer 10. The “trench” is a part of the semiconductor layer 10. The “trench” is filled with, for example, a conductor or an insulator.

The semiconductor layer 10 has a first face F1 and a second face F2 opposed to the first face F1. The semiconductor layer 10 is, for example, single crystal silicon. The thickness of the semiconductor layer 10 is, for example, equal to or more than 40 μm and equal to or less than 700 μm.

In this specification, a direction parallel to the first face F1 is referred to as a first direction. A direction parallel to the first face F1 and perpendicular to the first direction is referred to as a second direction. In this specification, the “depth” is defined as a distance in a direction toward the second face F2 with respect to the first face F1.

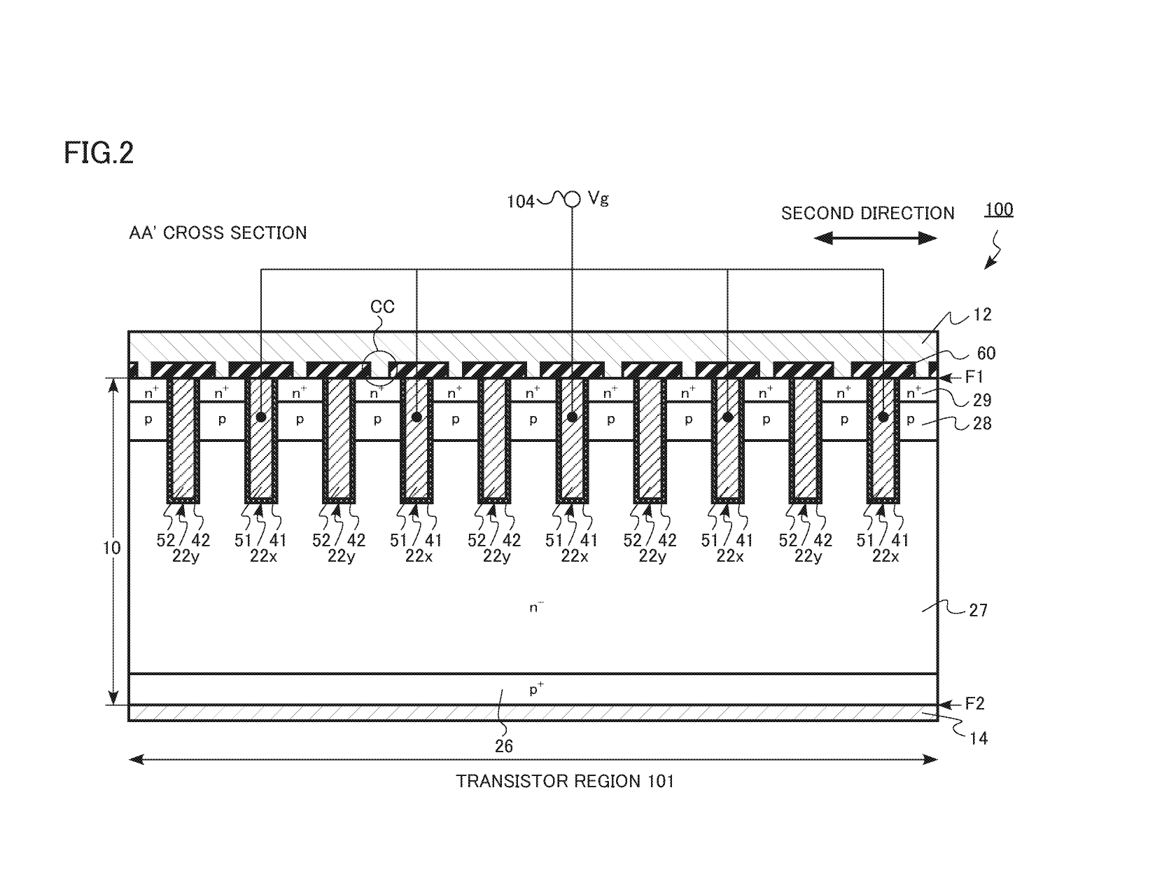

FIG. 2 is a schematic cross-sectional view of a part of the semiconductor device of the first embodiment. FIG. 2 is a schematic cross-sectional view of the transistor region. FIG. 2 is an AA’ cross section of FIG. 1.

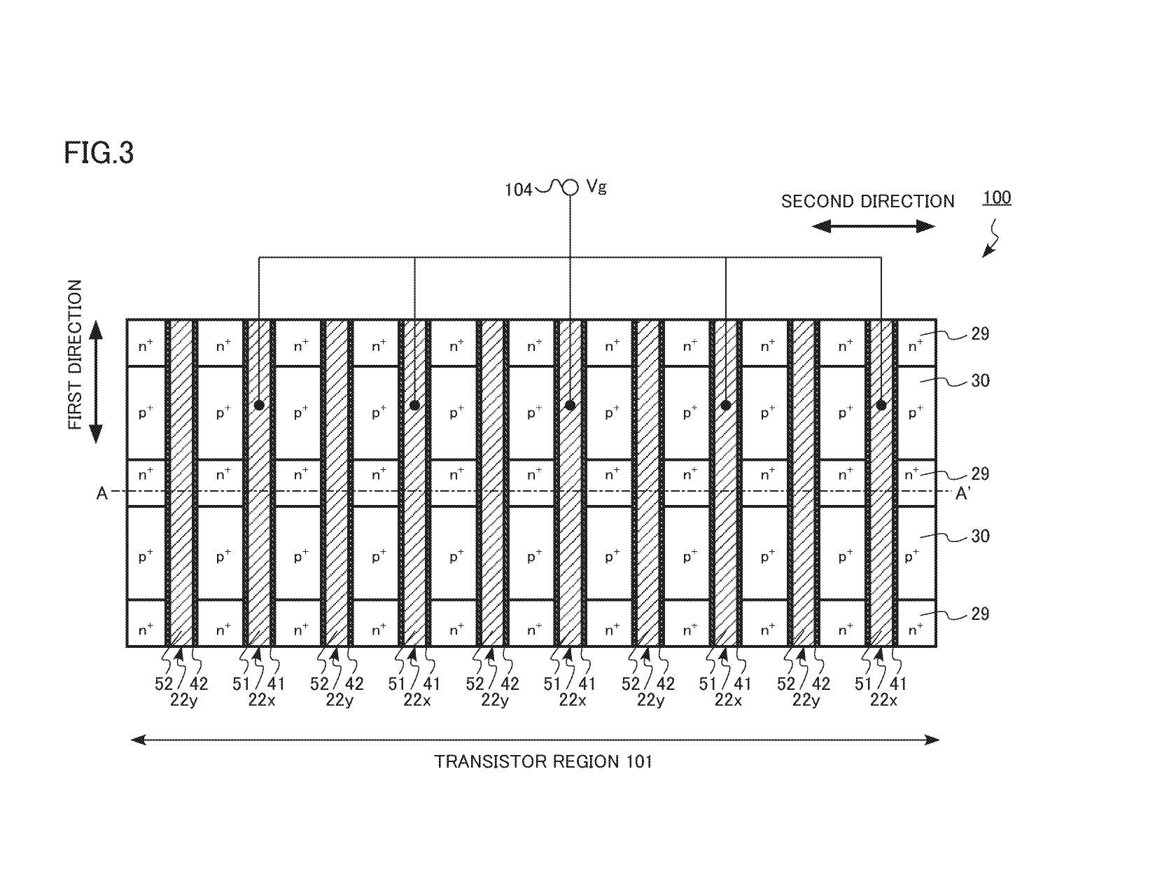

FIG. 3 is a schematic top view of a part of the semiconductor device of the first embodiment. FIG. 3 is a top view of the first face F1 of the transistor region. FIG. 2 is an AA’ cross section of FIG. 3.

The transistor region 101 includes the semiconductor layer 10, the upper electrode 12 (first electrode), the lower electrode 14 (second electrode), the gate insulating film 41, the dummy gate insulating film 42, the gate electrode 51, the dummy gate electrode 52, and the interlayer insulating layer 60.

In the semiconductor layer 10 of the transistor region 101, the trenches 22 of the second group, the collector region 26 (sixth semiconductor region), the drift region 27 (second semiconductor region), the cell base region 28 (seventh semiconductor region), the cell emitter region 29 (eighth semiconductor region), and the cell contact region 30 are provided.

The upper electrode 12 is provided on a side of the first face F1 of the semiconductor layer 10. At least a part of the upper electrode 12 is in contact with the first face F1 of the semiconductor layer 10.

The upper electrode 12 functions as an emitter electrode of the IGBT in the transistor region 101. The upper electrode 12 is, for example, metal.

The upper electrode 12 is in contact with the cell emitter region 29 and the cell contact region 30. The upper electrode 12 is electrically connected to the cell emitter region 29. Hereinafter, a portion where the upper electrode 12 is in contact with the cell emitter region 29 and the cell contact region 30 is referred to as a cell contact CC.

The upper electrode 12 is in contact with the cell contact region 30. The upper electrode 12 is electrically connected to the cell contact region 30. The upper electrode 12 is electrically connected to the cell base region 28 via the cell contact region 30.

The lower electrode 14 is provided on a side of the second face F2 of the semiconductor layer 10. At least a part of the lower electrode 14 is in contact with the second face F2 of the semiconductor layer 10.

The lower electrode 14 functions as a collector electrode of the IGBT in the transistor region 101. The lower electrode 14 is, for example, metal.

The lower electrode 14 is in contact with the collector region 26 in the transistor region 101. The lower electrode 14 is electrically connected to the collector region 26 in the transistor region 101.

The collector region 26 is a p⁺-type semiconductor region. The collector region 26 is in contact with the second face F2. The collector region 26 is electrically connected to the lower electrode 14. The collector region 26 is in contact with the lower electrode 14. The collector region 26 is a hole supply source when the IGBT is in an on-state.

The drift region 27 is an n⁻ -type semiconductor region. The drift region 27 is provided between the collector region 26 and the first face F1.

The drift region 27 is a path of an on-current when the IGBT is in an on-state. The drift region 27 is depleted when the IGBT is in an off-state, and has a function of maintaining a breakdown voltage of the IGBT.

The cell base region 28 is a p-type semiconductor region. The cell base region 28 is provided between the drift region 27 and the first face F1. The cell base region 28 sandwiches the drift region 27 with the collector region 26.

In a region of the cell base region 28 opposed to the gate electrode 51 to which a gate voltage Vg is applied, an n-type inversion layer is formed when the IGBT is in an on-state. The cell base region 28 functions as a channel region of a transistor.

The cell emitter region 29 is an n⁺-type semiconductor region. The cell emitter region 29 is provided between the cell base region 28 and the first face F1. The cell emitter region 29 is in contact with the gate insulating film 41.

The n-type impurity concentration of the cell emitter region 29 is higher than the n-type impurity concentration of the drift region 27.

The cell emitter region 29 is in contact with the upper electrode 12. The cell emitter region 29 is electrically connected to the upper electrode 12. The cell emitter region 29 is an electron-supply source when a transistor is in an on-state.

The cell contact region 30 is a p⁺ -type semiconductor region. The cell contact region 30 is provided between the cell base region 28 and the first face F1. The cell contact region 30 is in contact with the upper electrode 12. The cell contact region 30 is electrically connected to the upper electrode 12.

The p-type impurity concentration of the cell contact region 30 is higher than the p-type impurity concentration of the cell base region 28.

The trenches 22 of the second group are provided on a side of the first face F1 of the semiconductor layer 10. The trenches 22 of the second group are grooves provided in the semiconductor layer 10. The trenches 22 of the second group are a part of the semiconductor layer 10.

As illustrated in FIG. 3, the trenches 22 of the second group extend in the first direction parallel to the first face F1 on the first face F1. The trenches 22 of the second group each have a stripe shape. The trenches 22 of the second group are repeatedly disposed with equal to or more than 10 trenches in the second direction perpendicular to the first direction.

The trenches 22 of the second group are in contact with the drift region 27, the cell base region 28, and the cell emitter region 29. The trenches 22 of the second group penetrate through the cell base region 28 and reach the drift region 27.

The trenches 22 of the second group include the gate trenches 22x and the dummy gate trenches 22y. The gate trenches 22x and the dummy gate trenches 22y are alternately disposed, for example, in the second direction one by one.

The gate electrode 51 is provided in the gate trench 22x. The gate electrode 51 is, for example, a semiconductor or metal. The gate electrode 51 is, for example, amorphous silicon or polycrystalline silicon, which contains the n-type impurity or the p-type impurity.

The gate electrode 51 is electrically connected to the gate electrode pad 104.

The gate insulating film 41 is provided between the gate electrode 51 and the semiconductor layer 10. The gate insulating film 41 is provided between the gate electrode 51 and the drift region 27, between the gate electrode 51 and the cell base region 28, and between the gate electrode 51 and the cell emitter region 29. The gate electrode 51 is in contact with the drift region 27, the cell base region 28, and the cell emitter region 29. The gate insulating film 41 is, for example, silicon oxide.

The dummy gate electrode 52 is provided in the dummy gate trench 22y. The dummy gate electrode 52 is, for example, a semiconductor or metal. The dummy gate electrode 52 is, for example, amorphous silicon or polycrystalline silicon, which contains the n-type impurity or the p-type impurity.

The dummy gate electrode 52 is electrically connected, for example, to the upper electrode 12.

The dummy gate insulating film 42 is provided between the dummy gate electrode 52 and the semiconductor layer 10. The dummy gate insulating film 42 is provided between the dummy gate electrode 52 and the drift region 27, between the dummy gate electrode 52 and the cell base region 28, and between the dummy gate electrode 52 and the cell emitter region 29. The dummy gate insulating film 42 is in contact with the drift region 27, the cell base region 28, and the cell emitter region 29. The dummy gate insulating film 42 is, for example, silicon oxide.

Note that the dummy gate trench 22y may not be provided in the transistor region 101. In the transistor region 101, the ratio of the gate trenches 22x in the trenches 22 of the second group and the ratio of the dummy gate trenches 22y in the trenches 22 of the second group may not be the same.

The interlayer insulating layer 60 is provided between the gate electrode 51 and the upper electrode 12 and between the dummy gate electrode 52 and the upper electrode 12. The interlayer insulating layer 60 electrically isolates the gate electrode 51 from the upper electrode 12 and the dummy gate electrode 52 from the upper electrode 12. The interlayer insulating layer 60 is, for example, silicon oxide.

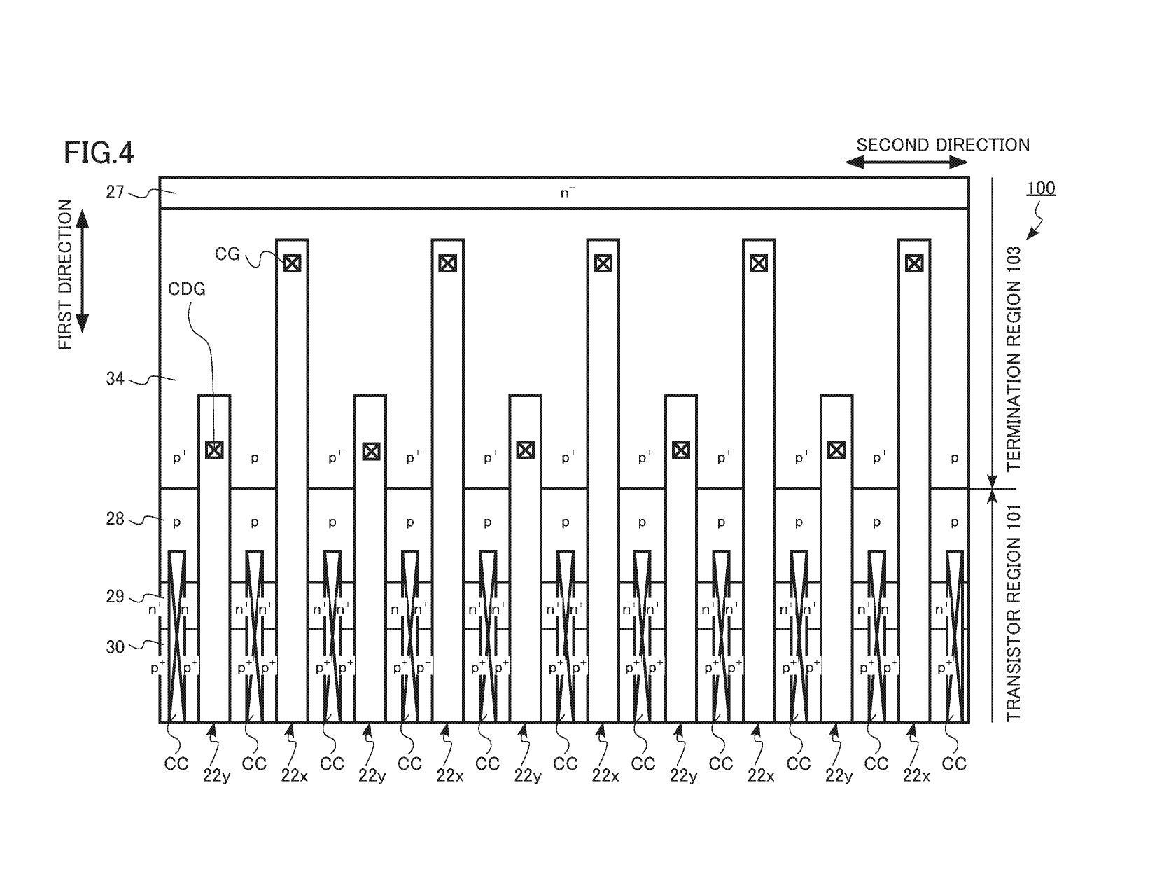

FIG. 4 is a schematic top view of a part of the semiconductor device of the first embodiment. FIG. 4 is a top view of the first face F1 including a boundary portion between the transistor region and the termination region. FIG. 4 is a top view of a region R1 surrounded by a dotted line in FIG. 1.

FIG. 4 illustrates a layout pattern of the trenches 22 of the second group. FIG. 4 illustrates layout patterns of the drift region 27, the guard ring region 34, the cell base region 28, the cell emitter region 29, and the cell contact region 30.

The termination region 103 includes the trenches 22 of the second group. As illustrated in FIG. 4, in the termination region 103, a minimum distance in the second direction between any two adjacent trenches in the trenches 22 of the second group is substantially the same. In other words, in the termination region 103, the trenches 22 of the second group are disposed at substantially equal intervals in the second direction.

In the termination region 103, the trenches 22 of the second group are not physically connected to each other. Each of the trenches 22 of the second group is physically independent.

For example, in a gate contact CG illustrated in FIG. 4, the gate electrode 51 in the gate trench 22x is connected to a gate wiring (not illustrated). The gate wiring is electrically connected to the gate electrode pad 104.

For example, in a dummy gate contact CDG illustrated in FIG. 4, the dummy gate electrode 52 in the dummy gate trench 22y is connected to the upper electrode 12 (not illustrated).

FIG. 4 also illustrates a pattern of the cell contact CC provided between two adjacent trenches 22 of the second group.

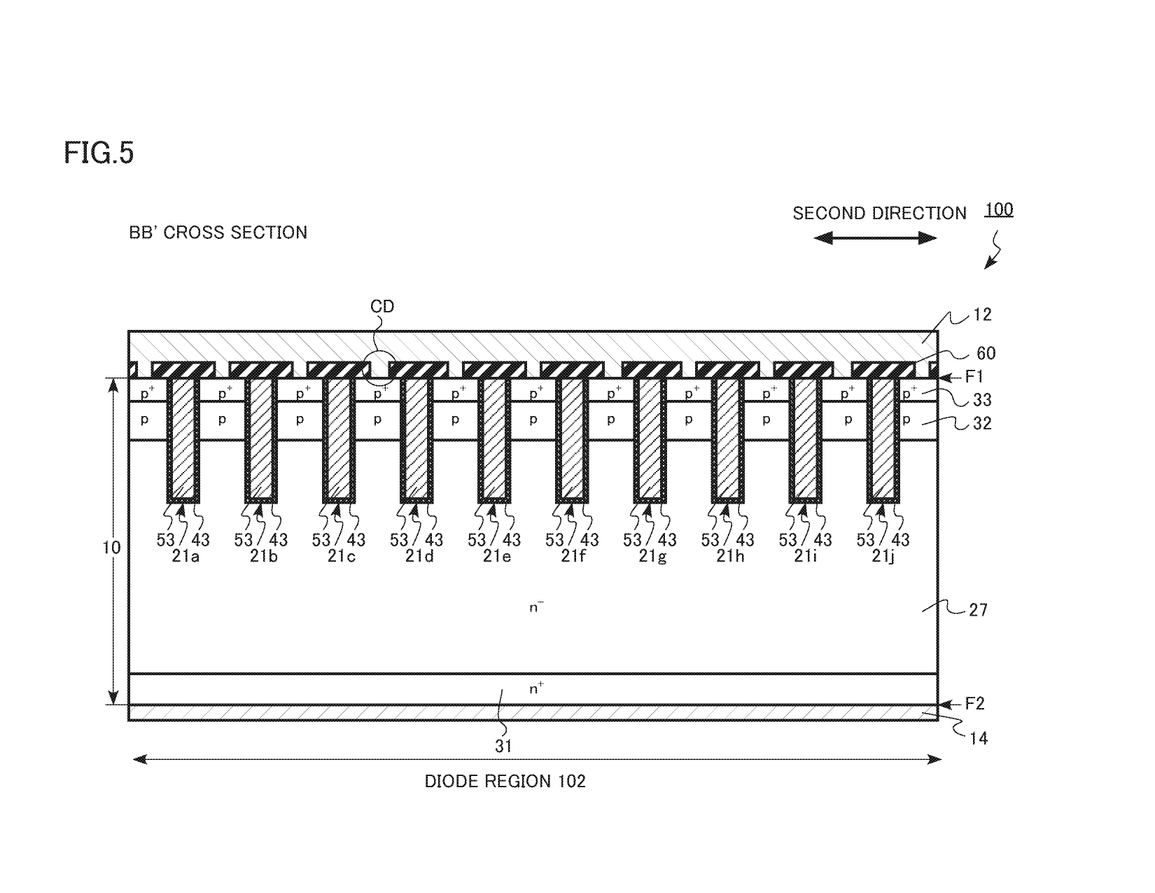

FIG. 5 is a schematic cross-sectional view of a part of the semiconductor device of the first embodiment. FIG. 5 is a schematic cross-sectional view of the diode region 102. FIG. 5 is a BB’ cross section of FIG. 1.

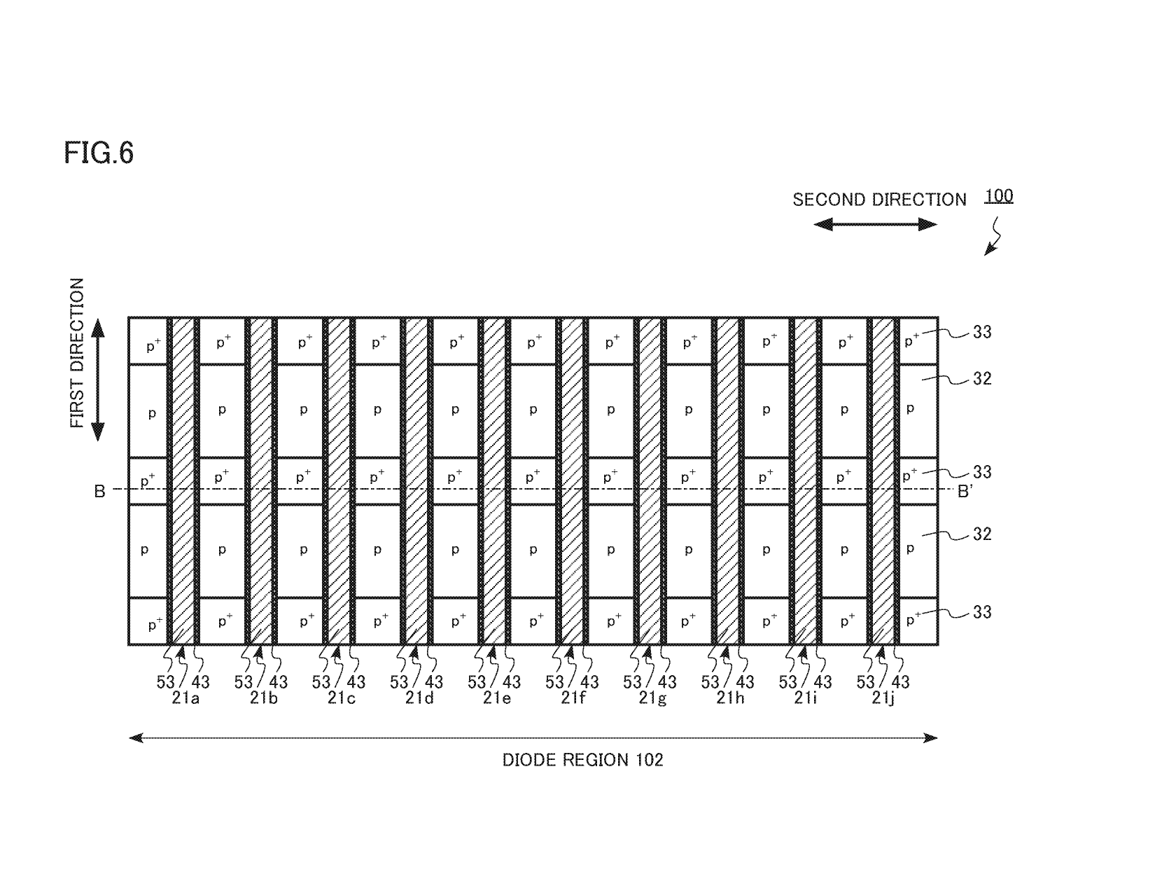

FIG. 6 is a schematic top view of a part of the semiconductor device of the first embodiment. FIG. 6 is a top view of the first face F1 of the diode region. FIG. 5 is a BB’ cross section of FIG. 6.

The diode region 102 includes the semiconductor layer 10, the upper electrode 12 (first electrode), the lower electrode 14 (second electrode), the trench insulating film 43, the conductive layer 53, and the interlayer insulating layer 60.

In the semiconductor layer 10 of the diode region 102, the trenches 21 of the first group, the cathode region 31 (first semiconductor region), the drift region 27 (second semiconductor region), the anode region 32 (third semiconductor region), and the diode contact region 33 are provided.

The trenches 21 of the first group include the A trench 21a, the B trench 21b, the C trench 21c, the D trench 21d, the E trench 21e, the F trench 21f, the G trench 21g, the H trench 21h, the I trench 21i, and the J trench 21j.

The upper electrode 12 functions as an anode electrode of a diode in the diode region 102. The upper electrode 12 is in contact with the diode contact region 33. The upper electrode 12 is electrically connected to the diode contact region 33. The upper electrode 12 is electrically connected to the anode region 32 via the diode contact region 33. The upper electrode 12 is also in contact with, for example, the anode region 32. Hereinafter, a portion where the upper electrode 12 is in contact with the diode contact region 33 and the anode region 32 is referred to as a diode contact CD.

The lower electrode 14 functions as a cathode electrode of a diode in the diode region 102. The lower electrode 14 is in contact with the cathode region 31.

The cathode region 31 is an n⁺-type semiconductor region. The cathode region 31 is in contact with the second face F2. The cathode region 31 is an electron-supply source when the diode is in an on-state. The cathode region 31 is in contact with the lower electrode 14.

The drift region 27 is an n⁻-type semiconductor region. The drift region 27 is provided between the cathode region 31 and the first face F1. The n-type impurity concentration of the drift region 27 is lower than the n-type impurity concentration of the cathode region 31.

The drift region 27 is a path of an on-current when the diode is in an on-state.

The anode region 32 is a p-type semiconductor region. The anode region 32 is provided between the drift region 27 and the first face F1. The anode region 32 sandwiches the drift region 27 with the cathode region 31.

The anode region 32 is a hole supply source when the diode is in an on-state.

The p-type impurity concentration of the anode region 32 is, for example, lower than the p-type impurity concentration of the guard ring region 34. The depth of the anode region 32 is, for example, the same as the depth of the cell base region 28. An n-type layer having an impurity concentration higher than that of the drift region 27 may be formed immediately below the cell base region 28. In this case, the depth of the anode region 32 may be deeper than that of the cell base region 28.

The diode contact region 33 is a p⁺-type semiconductor region. The diode contact region 33 is provided between the anode region 32 and the first face F1.

The diode contact region 33 is in contact with the upper electrode 12. The diode contact region 33 is electrically connected to the upper electrode 12.

The p-type impurity concentration of the diode contact region 33 is higher than the p-type impurity concentration of the anode region 32.

The trenches 21 of the first group are provided on a side of the first face F1 of the semiconductor layer 10. The trenches 21 of the first group are grooves provided in the semiconductor layer 10. The trenches 21 of the first group are a part of the semiconductor layer 10.

As illustrated in FIG. 6, the trenches 21 of the first group extend in the first direction parallel to the first face F1 on the first face F1. The trenches 21 of the first group each have a stripe shape. The trenches 21 of the first group are repeatedly arranged in the second direction perpendicular to the first direction.

For example, the A trench 21a, the B trench 21b, the C trench 21c, the D trench 21d, the E trench 21e, the F trench 21f, the G trench 21g, the H trench 21h, the I trench 21i, and the J trench 21j are disposed in this order in the second direction.

The trenches 21 of the first group are in contact with the drift region 27 and the anode region 32. The trenches 21 of the first group penetrate through the anode region 32 and reach the drift region 27.

The conductive layer 53 is provided in each of the trenches 21 of the first group. The conductive layer 53 is, for example, a semiconductor or metal. The conductive layer 53 is, for example, amorphous silicon or polycrystalline silicon, which contains the n-type impurity or the p-type impurity.

The conductive layer 53 is electrically connected, for example, to the upper electrode 12.

The trench insulating film 43 is provided between the conductive layer 53 and the semiconductor layer 10. The trench insulating film 43 is provided between the conductive layer 53 and the drift region 27 and between the conductive layer 53 and the anode region 32. The conductive layer 53 is in contact with the drift region 27 and the anode region 32. The conductive layer 53 is, for example, silicon oxide.

The interlayer insulating layer 60 is provided between the conductive layer 53 and the upper electrode 12. The interlayer insulating layer 60 electrically isolates the conductive layer 53 from the upper electrode 12.

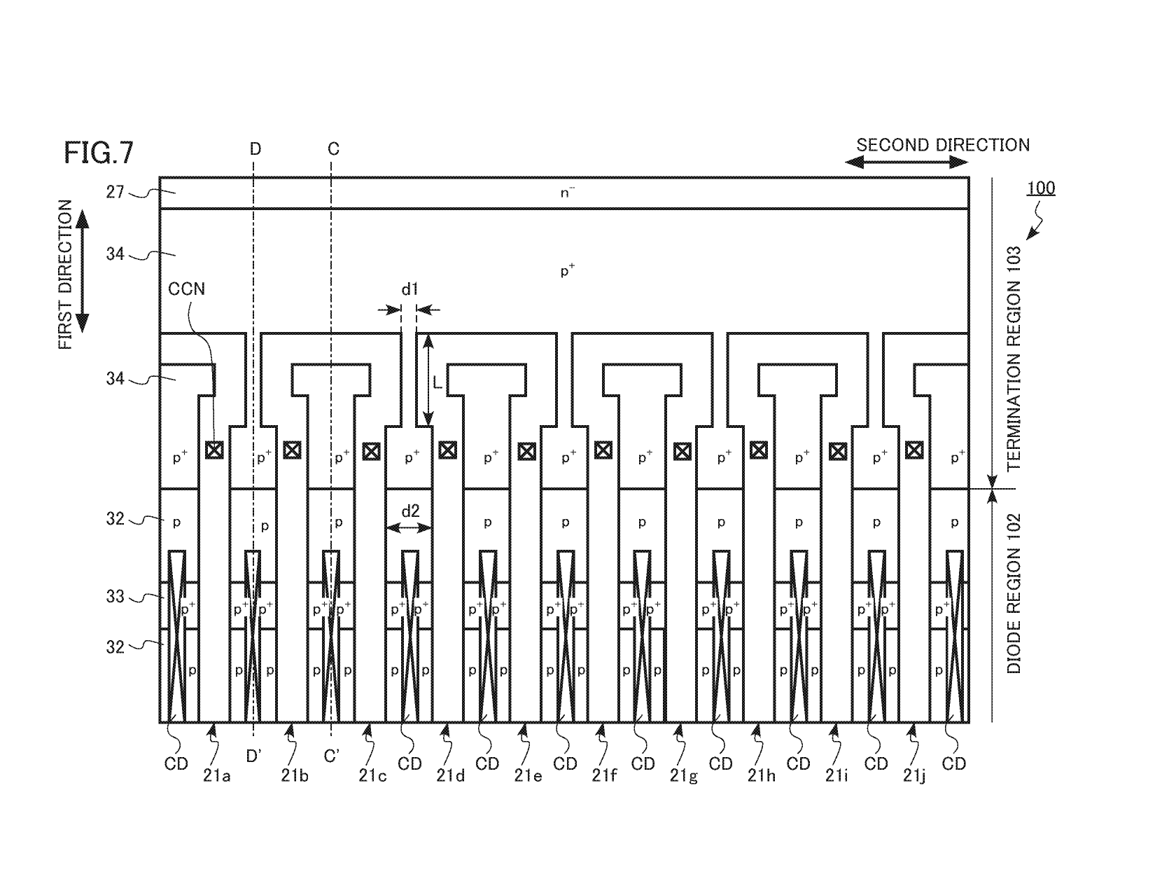

FIG. 7 is a schematic top view of a part of the semiconductor device of the first embodiment. FIG. 7 is a top view of the first face F1 including a boundary portion between the diode region and the termination region. FIG. 7 is a top view of a region R2 surrounded by a dotted line in FIG. 1.

FIG. 7 illustrates a layout pattern of the trenches 21 of the first group. FIG. 7 illustrates layout patterns of the drift region 27, the guard ring region 34, the anode region 32, and the diode contact region 33.

The termination region 103 includes the trenches 21 of the first group. The termination region 103 includes the A trench 21a, the B trench 21b, the C trench 21c, the D trench 21d, the E trench 21e, the F trench 21f, the G trench 21g, the H trench 21h, the I trench 21i, and the J trench 21j.

In the termination region 103, the trenches 21 of the first group include a first trench, a second trench, a third trench, and a fourth trench. The first trench and the second trench are physically connected in the termination region 103, and the third trench and the fourth trench are physically connected in the termination region 103. The second trench and the third trench are adjacent in the second direction, and a first minimum distance in the second direction between the second trench and the third trench in the termination region 103 is smaller than a second minimum distance in the second direction between the second trench and the third trench in the diode region 102.

The B trench 21b is an example of the first trench. The C trench 21c is an example of the second trench. The D trench 21d is an example of the third trench. The E trench 21e is an example of the fourth trench.

The B trench 21b and the C trench 21c are physically connected in the termination region 103. The D trench 21d and the E trench 21e are physically connected in the termination region 103. The C trench 21c and the D trench 21d are adjacent to each other in the second direction.

A first minimum distance (d1 in FIG. 7) in the second direction between the C trench 21c and the D trench 21d in the termination region 103 is smaller than a second minimum distance (d2 in FIG. 7) in the second direction between the C trench 21c and the D trench 21d in the diode region 102.

The first minimum distance d1 is, for example, equal to or more than 1/10 and equal to or less than 1/2 of the second minimum distance d2.

For example, a length (L in FIG. 7) in the first direction of a portion where a distance in the second direction between the C trench 21c and the D trench 21d in the termination region 103 is equal to or less than the second minimum distance d2 is longer than the second minimum distance d2 and equal to or less than 100 times the second minimum distance d2.

For example, in a conductive layer contact CCN illustrated in FIG. 7, the conductive layer 53 in the trenches 21 of the first group is connected to the upper electrode 12 (not illustrated).

FIG. 7 also illustrates a pattern of the diode contact CD provided between two adjacent trenches 21 of the first group.

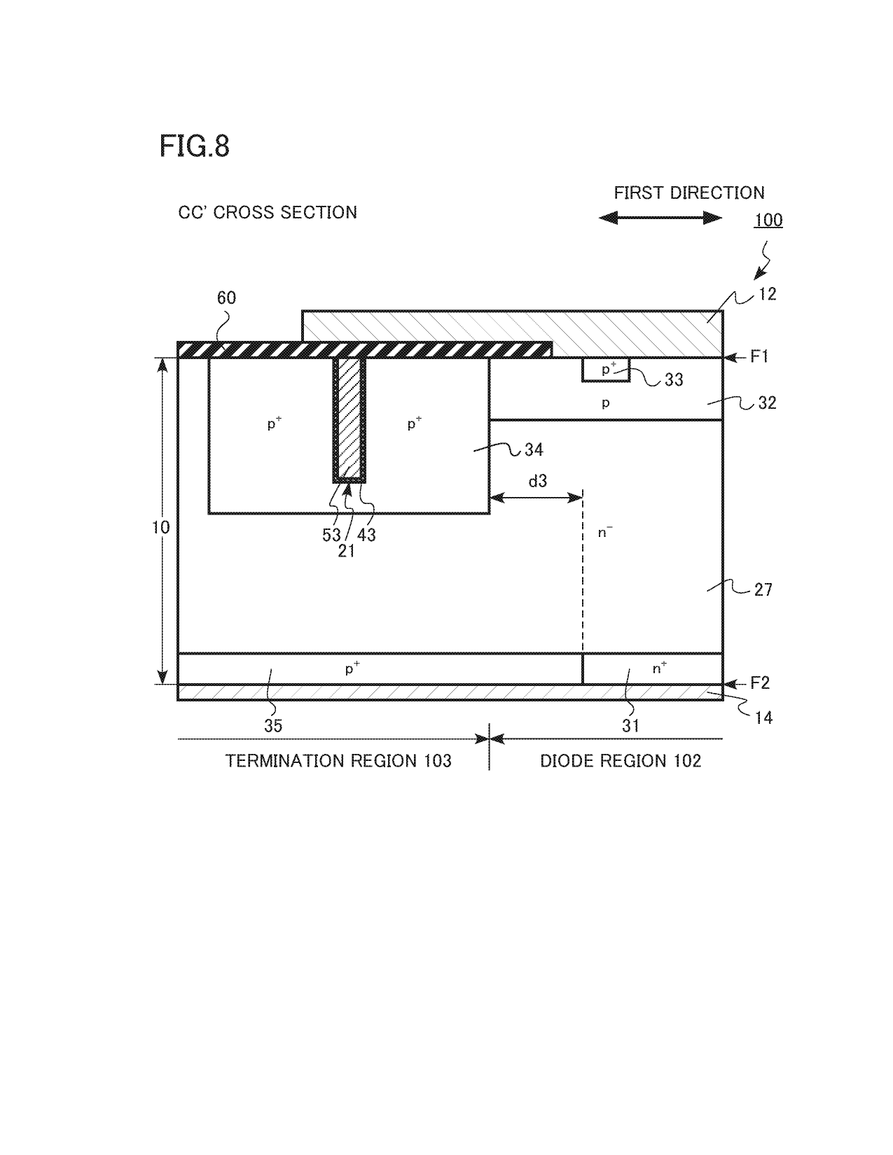

FIG. 8 is a schematic cross-sectional view of a part of the semiconductor device of the first embodiment. FIG. 8 is a schematic cross-sectional view including a boundary portion between the diode region 102 and the termination region 103. FIG. 8 is a CC’ cross section of FIG. 7.

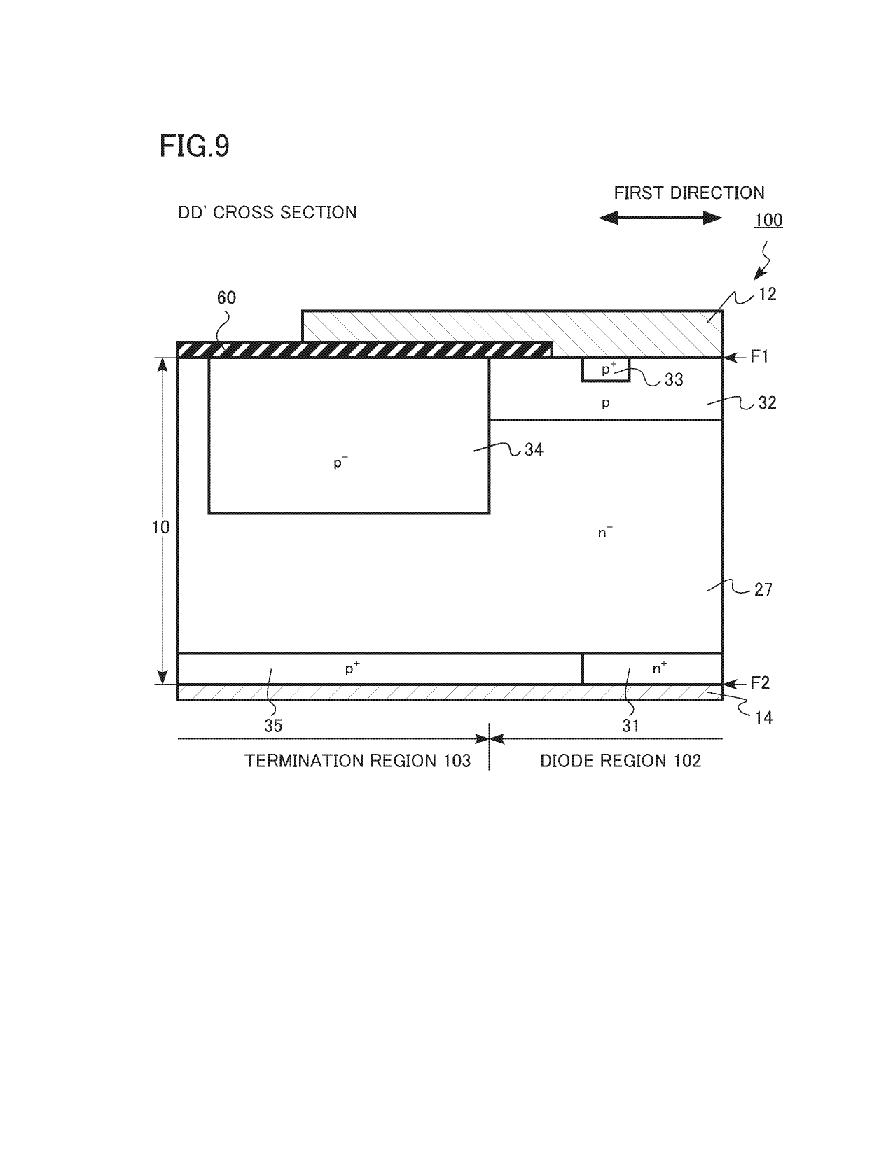

FIG. 9 is a schematic cross-sectional view of a part of the semiconductor device of the first embodiment. FIG. 9 is a schematic cross-sectional view including a boundary portion between the diode region 102 and the termination region 103. FIG. 9 is a DD’ cross section of FIG. 7.

The termination region 103 includes the semiconductor layer 10, the upper electrode 12 (first electrode), the lower electrode 14 (second electrode), the gate insulating film 41, the dummy gate insulating film 42, the trench insulating film 43, the gate electrode 51, the dummy gate electrode 52, the conductive layer 53, and the interlayer insulating layer 60.

In the semiconductor layer 10 of the termination region 103, the trenches 21 of the first group, the trenches 22 of the second group, the drift region 27, the guard ring region 34 (fourth semiconductor region), and the termination back surface p region 35 (fifth semiconductor region) are provided.

In the termination region 103, a parasitic diode including a pn junction between the guard ring region 34 and the drift region 27 is formed.

The termination back surface p region 35 is a p⁺-type semiconductor region. The termination back surface p region 35 is in contact with the second face F2. The termination back surface p region 35 is in contact with the lower electrode 14.

A boundary between the termination back surface p region 35 and the cathode region 31 exists, for example, in the diode region 102. A distance (d3 in FIG. 8) in the first direction between the guard ring region 34 and the cathode region 31 is, for example, equal to or more than 100 μm and equal to or less than 300 μm.

Note that it is not essential to provide the termination back surface p region 35. For example, the cathode region 31 may be provided below the guard ring region 34 of the termination region 103.

The drift region 27 is an n⁻-type semiconductor region. The drift region 27 is provided between the termination back surface p region 35 and the first face F1.

The drift region 27 is a path of an on-current when the parasitic diode is in an on-state.

The guard ring region 34 is a p-type semiconductor region. The guard ring region 34 is provided between the drift region 27 and the first face F1. The guard ring region 34 sandwiches the drift region 27 with the termination back surface p region 35.

The depth of the guard ring region 34 is deeper than the depth of the anode region 32. The depth of the guard ring region 34 is desirably deeper than the depth of the trenches 21 of the first group. The depth of the guard ring region 34 is desirably deeper than the trenches 22 of the second group.

The guard ring region 34 surrounds the transistor region 101 and the diode region 102. The guard ring region 34 is annularly provided on the first face F1. The guard ring region 34 has a function of lessening the intensity of the electric field applied to the termination portion of the pn junction of the transistor region 101 and the diode region 102.

The guard ring region 34 is a hole supply source when the parasitic diode is in an on-state.

For example, an annular p-type region may be provided as a guard ring outside the guard ring region 34 of the termination region 103 so as to surround the guard ring region 34.

The p-type impurity concentration of the guard ring region 34 is, for example, higher than the p-type impurity concentration of the anode region 32. The p-type impurity concentration of the guard ring region 34 is, for example, equal to or more than 5 times and equal to or less than 100 times the p-type impurity concentration of the anode region 32.

The interlayer insulating layer 60 is provided between the semiconductor layer 10 and the upper electrode 12. The interlayer insulating layer 60 is provided, for example, between the guard ring region 34 and the upper electrode 12.

Next, the function and effect of the semiconductor device of the first embodiment will be described.

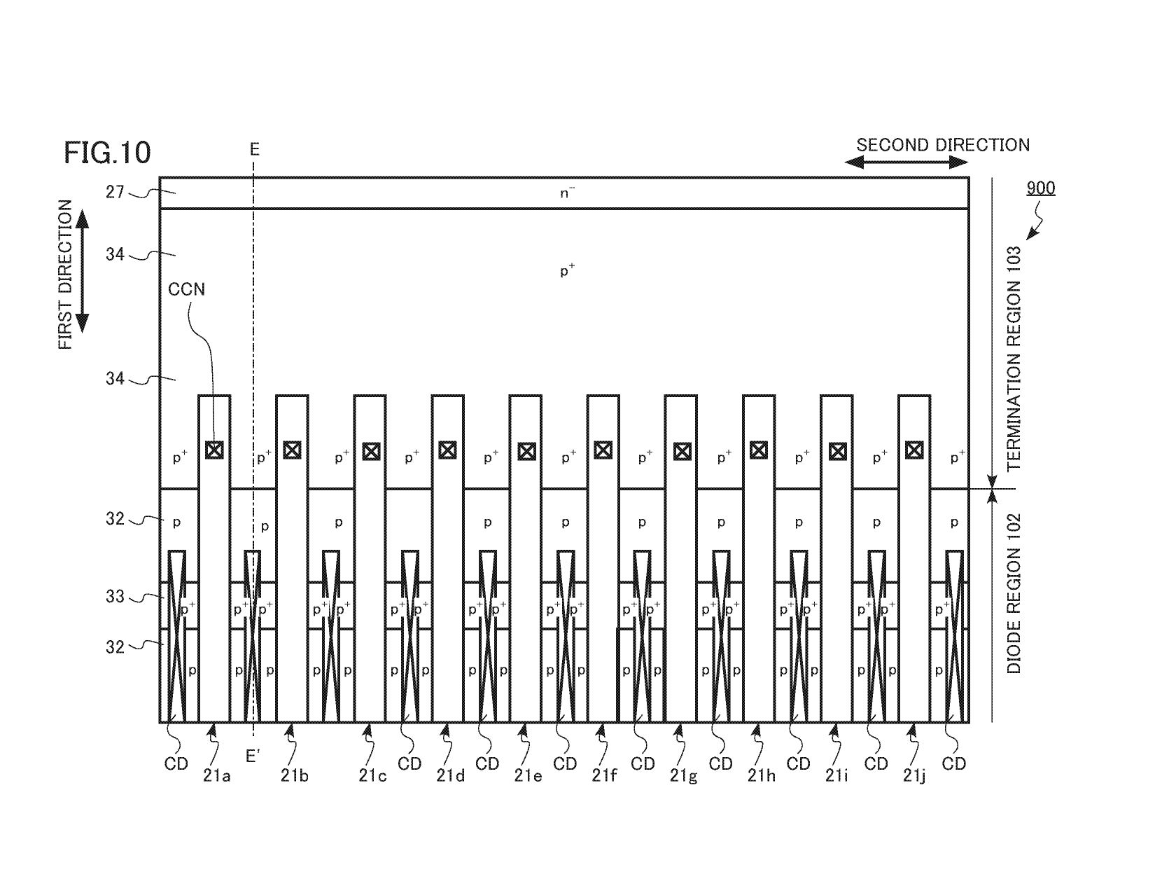

FIG. 10 is a schematic cross-sectional view of a part of a semiconductor device of a comparative example. FIG. 10 is a view corresponding to FIG. 7 of the first embodiment.

The semiconductor device of the comparative example is an RC-IGBT 900 in which an IGBT and a free wheeling diode are formed on the same semiconductor chip. The RC-IGBT 900 of the comparative example is different from the RC-IGBT 100 of the first embodiment in that, in the termination region, a minimum distance in the second direction between any two adjacent trenches in the trenches of the second group is substantially the same, and the trenches of the second group are not physically connected to each other.

As illustrated in FIG. 10, in the termination region 103, a minimum distance in the second direction between any two adjacent trenches in the trenches 21 of the first group is substantially the same. In other words, in the termination region 103, the trenches 21 of the first group are disposed at substantially equal intervals in the second direction.

In the termination region 103, the trenches 22 of the second group are not physically connected to each other. Each of the trenches 22 of the second group is independent.

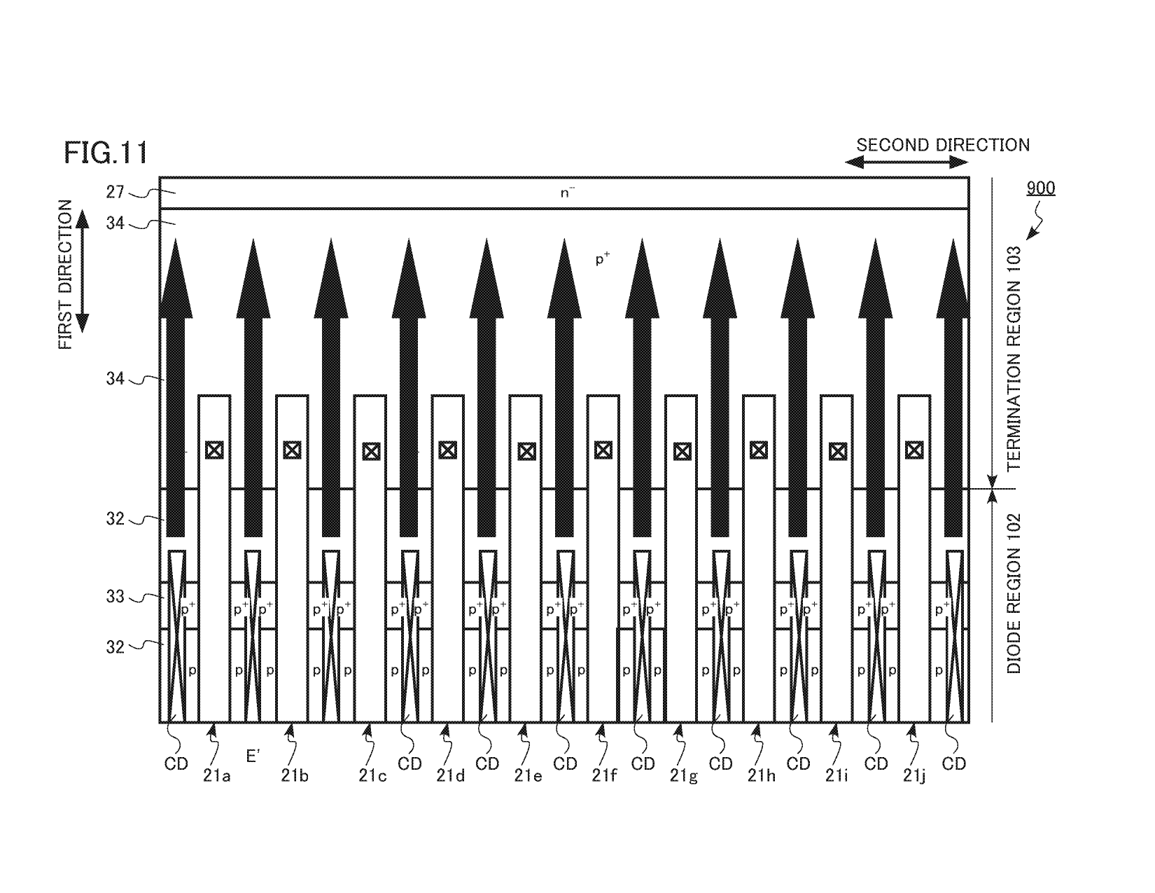

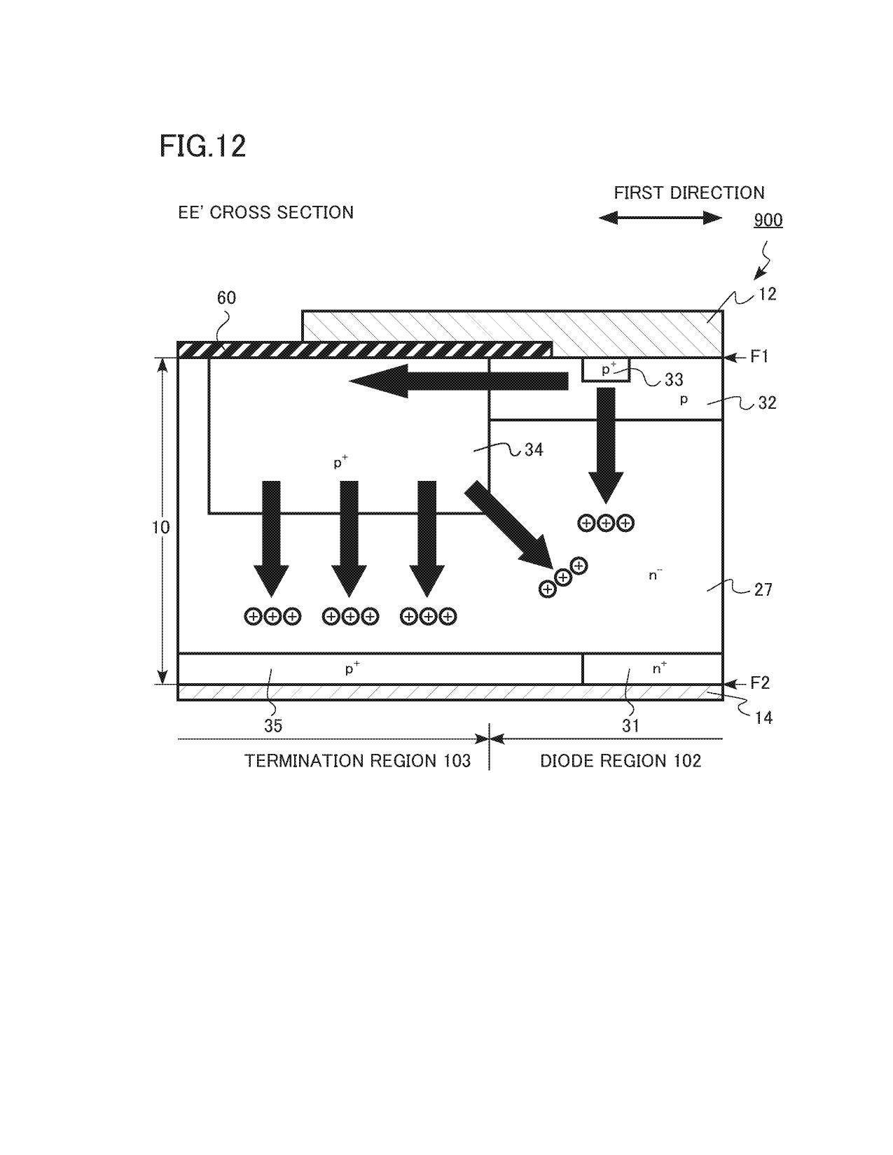

FIGS. 11 and 12 are explanatory diagrams of the function and effect of the semiconductor device of the first embodiment. FIGS. 11 and 12 are diagrams illustrating a current flow when the diode of the diode region 102 of the RC-IGBT 900 of the comparative example is in a conducting state. FIG. 11 is a view corresponding to FIG. 10. FIG. 12 is an EE’ cross section of FIG. 10.

In FIGS. 11 and 12, the current flow is indicated by an arrow.

As illustrated in FIG. 11, when the diode of the diode region 102 is in a conducting state, a current flows from the anode region 32 toward the guard ring region 34. The current flows from the diode contact CD to the guard ring region 34 through spaces between the trenches 21 of the first group.

As illustrated in FIG. 12, the current flowing into the guard ring region 34 further flows into the drift region 27. In other words, holes are injected into the drift region 27. In other words, when the diode of the diode region 102 is in a conducting state, the parasitic diode of the termination region 103 is also in a conducting state, and holes are injected from the guard ring region 34 into the drift region 27. Therefore, holes are excessive in the drift region 27 near the termination region 103.

When holes are excessive in the drift region 27 near the termination region 103 of the diode region 102, discharge of the holes to the upper electrode 12 is delayed. Therefore, the reverse recovery current (Irr) at the time of reverse recovery of the diode increases, and the reverse recovery loss (Err) of the diode increases.

For example, when carriers accumulated in the drift region 27 in the termination region in an on-state are discharged to the emitter electrode or the anode electrode in an off-state, the current may concentrate in the guard ring region. At this time, the p-type impurity concentration of the guard ring region is increased in order to lessen current concentration. In that case, when the diode of the diode region 102 is in a conducting state, the injection amount of holes further increases in the drift region 27 near the termination region 103 in contact with the diode region 102, and the holes are further excessive. Therefore, the reverse recovery loss (Err) of the diode further increases.

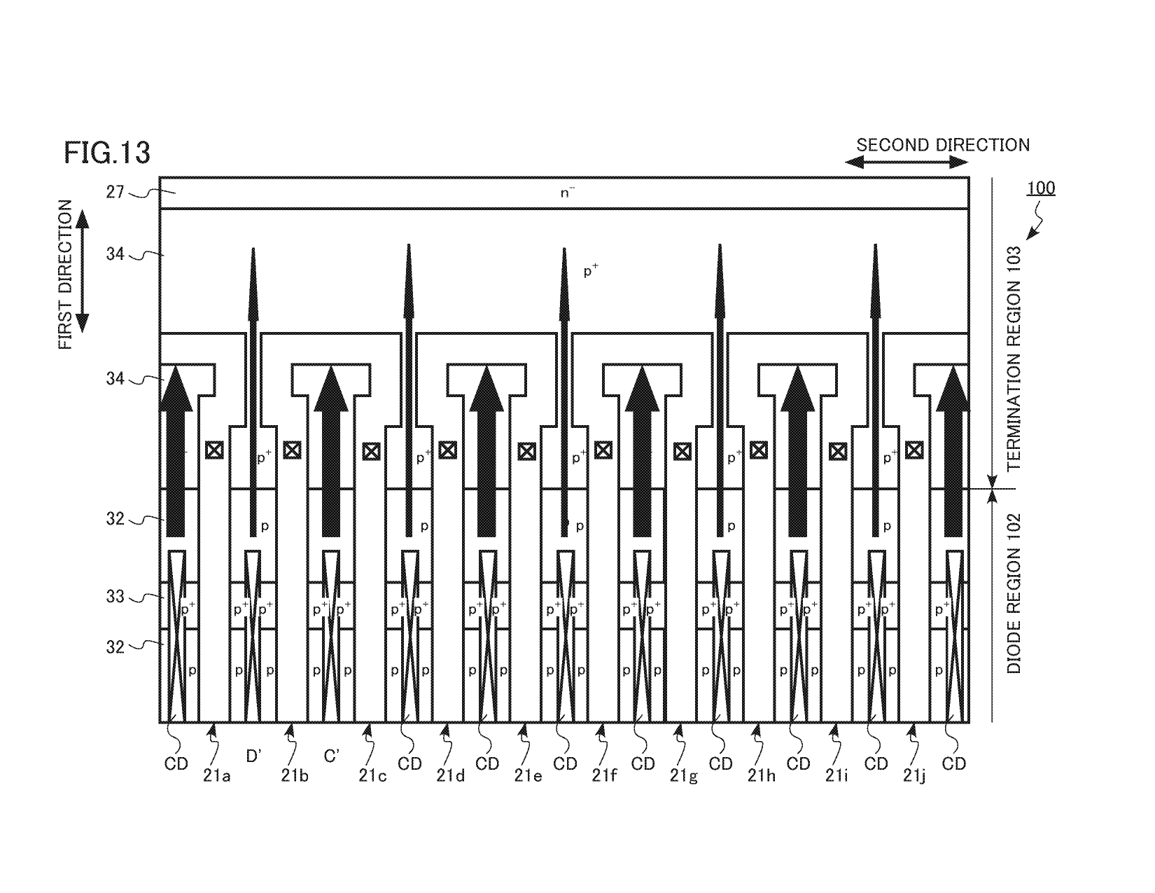

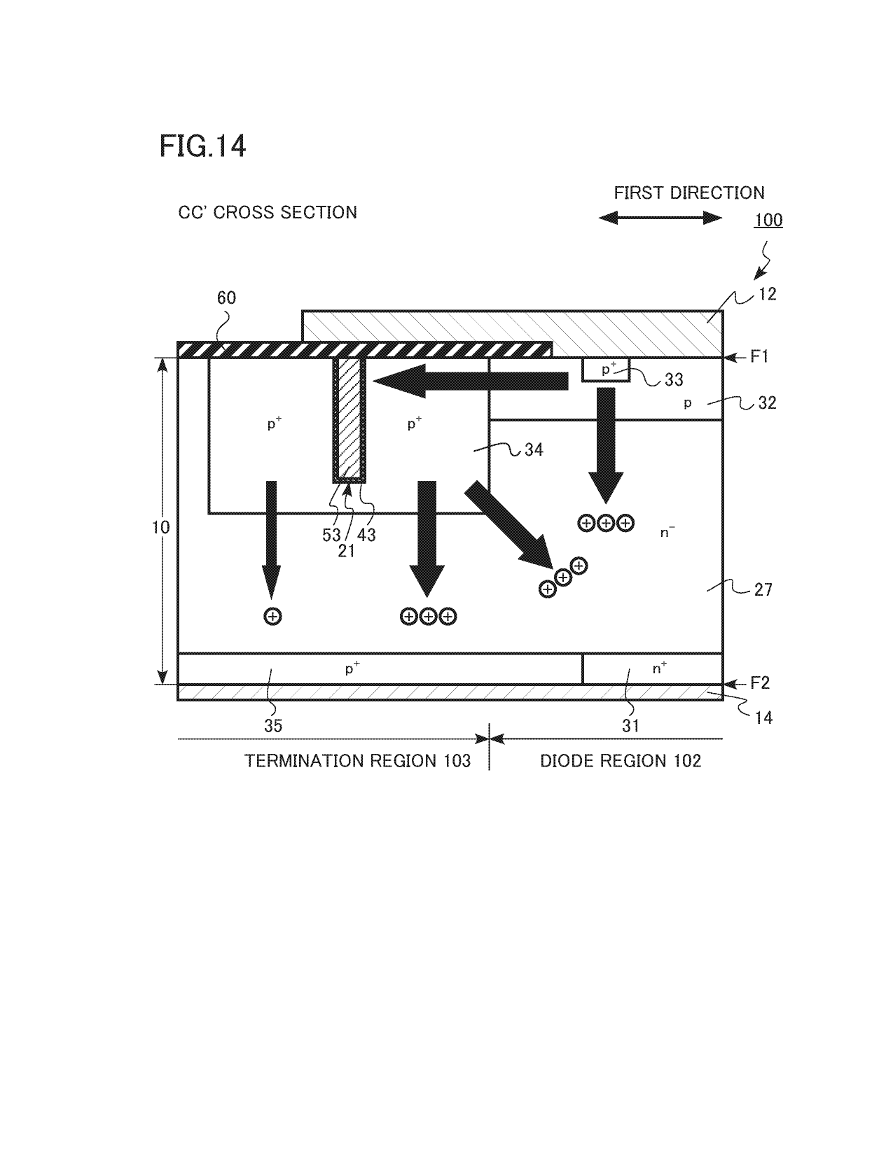

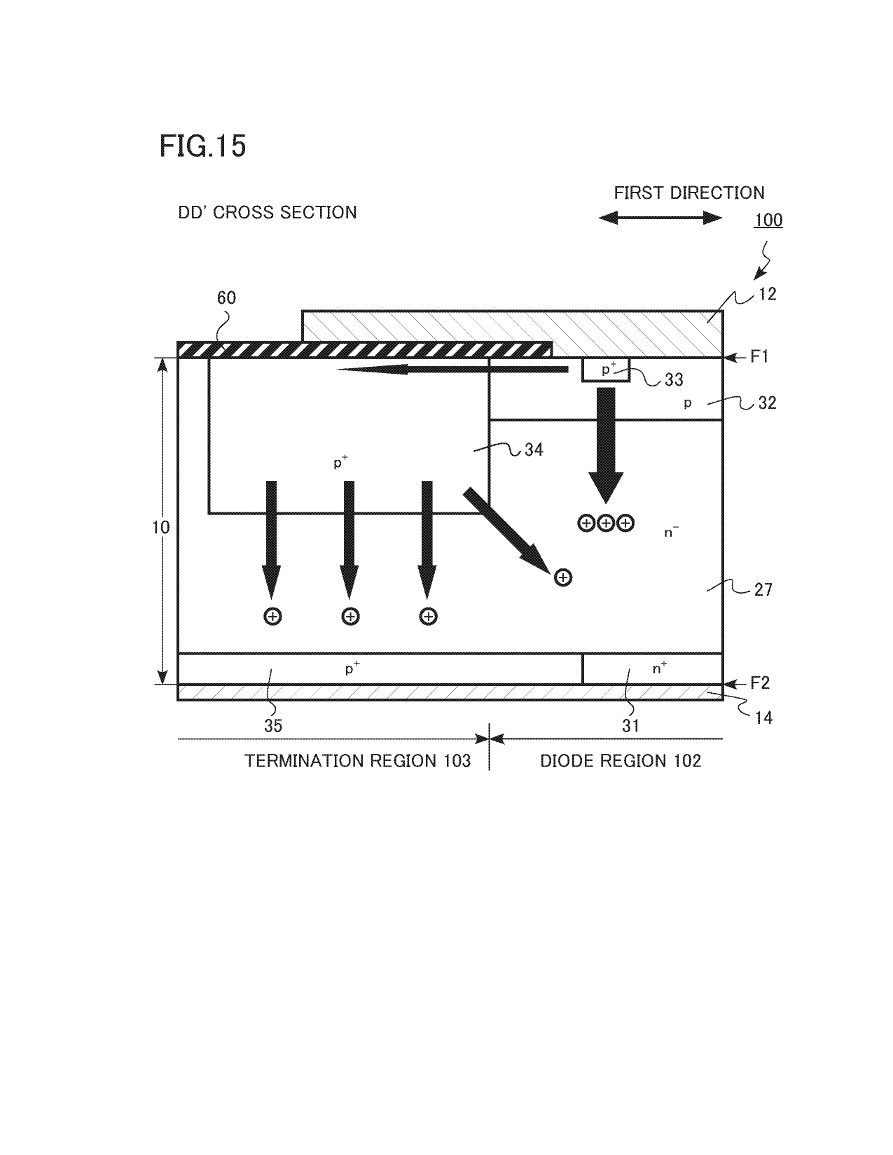

FIGS. 13, 14, and 15 are explanatory diagrams of the function and effect of the semiconductor device of the first embodiment. FIGS. 13, 14, and 15 are diagrams illustrating a current flow when the diode of the diode region 102 of the RC-IGBT 100 of the first embodiment is in a conducting state. FIG. 13 is a view corresponding to FIG. 7. FIG. 14 is a view corresponding to FIG. 8. FIG. 15 is a view corresponding to FIG. 9.

In FIGS. 13, 14, and 15, the current flow is indicated by an arrow.

As is clear from FIGS. 13 and 14, when the diode is in a conducting state, the current flowing between the two trenches 21 of the first group physically connected in the termination region 103, for example, the B trench 21b and the C trench 21c from the anode region 32 toward the guard ring region 34 is cut off by the trenches 21 of the first group. By setting the depth of the guard ring region 34 to be substantially the same as the depth of the trenches 21 of the first group, a diffusion layer is completely divided by the trenches, so that the current blocking effect is increased. However, even when the depth of the guard ring region 34 is deeper than the depth of the trenches 21 of the first group, the impurity concentration of the guard ring region 34 decreases from the surface toward the bottom portion. Therefore, even when the guard ring region 34 is not completely divided by the trenches, the bottom portion of the guard ring region 34 has high resistance, so that the current blocking effect can be obtained. Therefore, as illustrated in FIG. 14, particularly, holes injected into the drift region 27 from the guard ring region 34 outside the trenches 21 of the first group are reduced as compared with the RC-IGBT 900 of the comparative example.

As is clear from FIGS. 13 and 15, when the diode is in a conducting state, a current flowing from the anode region 32 toward the guard ring region 34 between the two adjacent trenches 21 of the first group not physically connected, for example, the C trench 21c and the D trench 21d is reduced as compared with the RC-IGBT 900 of the comparative example because the electrical resistance is increased by narrowing the space between the C trench 21c and the D trench 21d. Therefore, holes injected into the drift region 27 from the guard ring region 34 are reduced as compared with the RC-IGBT 900 of the comparative example.

When the diode is in the conducting state, holes injected into the drift region 27 from the guard ring region 34 are reduced, so that a reverse recovery current (Irr) at the time of reverse recovery of the diode is reduced, and a reverse recovery loss (Err) of the diode is reduced. Thus, according to the first embodiment, the reverse recovery loss (Err) of the RC-IGBT 100 is reduced.

In the RC-IGBT 100, the first minimum distance d1 is, for example, preferably equal to or less than 1/2, more preferably equal to or less than 1/3, and still more preferably equal to or less than 1/5 of the second minimum distance d2. The electrical resistance between the two trenches 21 of the first group further increases, holes injected into the drift region 27 from the guard ring region 34 are further reduced, and the reverse recovery loss (Err) of the RC-IGBT 100 is further reduced.

In the RC-IGBT 100, the length (L in FIG. 7) in the first direction of the portion where the distance in the second direction between the C trench 21c and the D trench 21d in the termination region 103 is equal to or less than the second minimum distance d2 is preferably longer than the second minimum distance d2, more preferably equal to or more than 2 times, still more preferably equal to or more than 5 times, and most preferably equal to or more than 10 times the second minimum distance d2. The electrical resistance between the two trenches 21 of the first group further increases, holes injected into the drift region 27 from the guard ring region 34 are further reduced, and the reverse recovery loss (Err) of the RC-IGBT 100 is further reduced.

The distance (d3 in FIG. 8) in the first direction between the guard ring region 34 and the cathode region 31 is preferably equal to or more than 100 μm. The distance d3 in the first direction between the guard ring region 34 and the cathode region 31 increases, so that holes injected into the drift region 27 from the guard ring region 34 are further reduced, and the reverse recovery loss (Err) of the RC-IGBT 100 is further reduced.

### First Modification

A semiconductor device of a first modification of the first embodiment is different from the semiconductor device of the first embodiment in that the trenches of the first group further include a fifth trench and a sixth trench, the fifth trench is provided between the first trench and the second trench, and the sixth trench is provided between the third trench and the fourth trench.

The semiconductor device of the first modification of the first embodiment is an RC-IGBT 110.

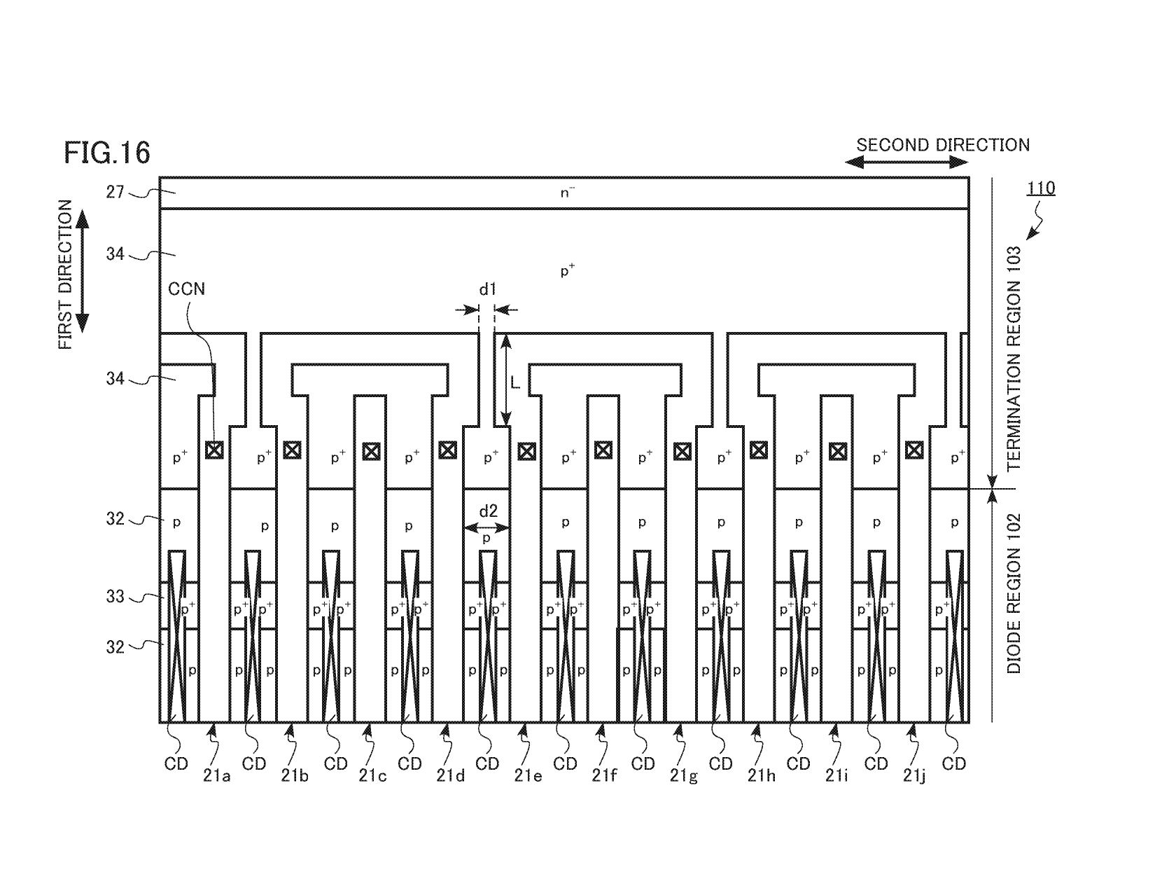

FIG. 16 is a schematic cross-sectional view of a part of the semiconductor device of the first modification of the first embodiment. FIG. 16 is a view corresponding to FIG. 7 of the first embodiment.

The B trench 21b is an example of the first trench. The D trench 21d is an example of the second trench. The E trench 21e is an example of the third trench. The G trench 21g is an example of the fourth trench. The C trench 21c is an example of the fifth trench. The F trench 21f is an example of the sixth trench.

The B trench 21b and the D trench 21d are physically connected in the termination region 103. The E trench 21e and the G trench 21g are physically connected in the termination region 103. The D trench 21d and the E trench 21e are adjacent to each other in the second direction.

The C trench 21c is provided between the B trench 21b and the D trench 21d. The F trench 21f is provided between the E trench 21e and the G trench 21g.

A first minimum distance (d1 in FIG. 16) in the second direction between the D trench 21d and the E trench 21e in the termination region 103 is smaller than a second minimum distance (d2 in FIG. 16) in the second direction between the D trench 21d and the E trench 21e in the diode region 102.

For example, a length (L in FIG. 16) in the first direction of a portion where a distance in the second direction between the D trench 21d and the E trench 21e in the termination region 103 is equal to or less than the second minimum distance d2 is longer than the second minimum distance d2 and equal to or less than 100 times the second minimum distance d2.

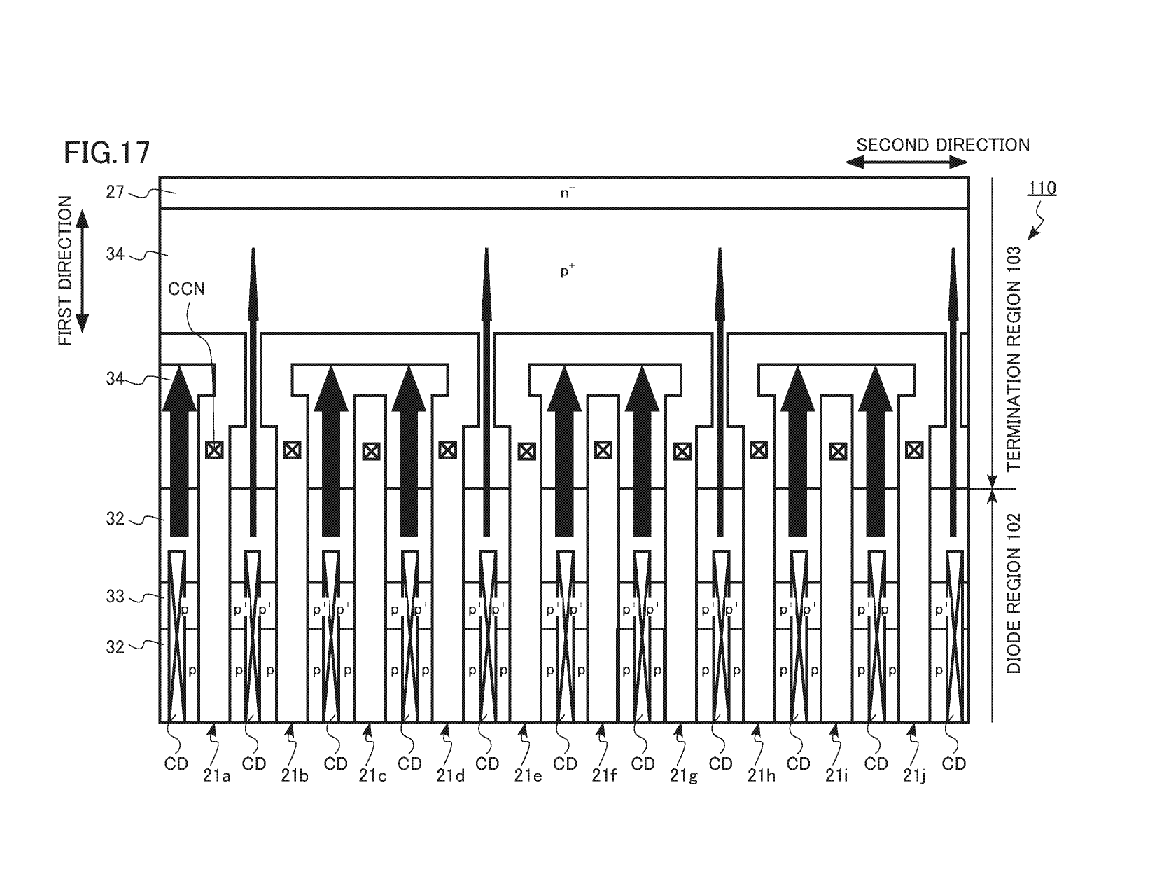

FIG. 17 is an explanatory diagram of the function and effect of the semiconductor device of the first modification of the first embodiment. FIG. 17 is a diagram illustrating a current flow when the diode of the diode region 102 of the RC-IGBT 110 of the first modification of the first embodiment is in a conducting state. FIG. 17 is a view corresponding to FIG. 13 of the first embodiment.

In FIG. 17, the current flow is indicated by an arrow.

As is clear from FIG. 17, when the diode is in a conducting state, the ratio of the current interrupted by the physically connected trenches 21 of the first group increases in the current flowing from the anode region 32 toward the guard ring region 34. The number of paths passing between the two adjacent trenches 21 of the first group not physically connected also decreases. Therefore, the current flowing from the anode region 32 toward the guard ring region 34 further decreases.

Therefore, holes injected into the drift region 27 from the guard ring region 34 are further reduced. Thus, the reverse recovery loss (Err) of the RC-IGBT 110 is further reduced.

According to the first modification of the first embodiment, as in the first embodiment, the reverse recovery loss (Err) of the RC-IGBT is reduced.

### Second Modification

A semiconductor device of a second modification of the first embodiment is different from the semiconductor device of the first modification of the first embodiment in that the trenches of the first group further include a seventh trench and an eighth trench, the seventh trench is provided between the fifth trench and the second trench, and the eighth trench is provided between the sixth trench and the fourth trench.

The semiconductor device of the second modification of the first embodiment is an RC-IGBT 120.

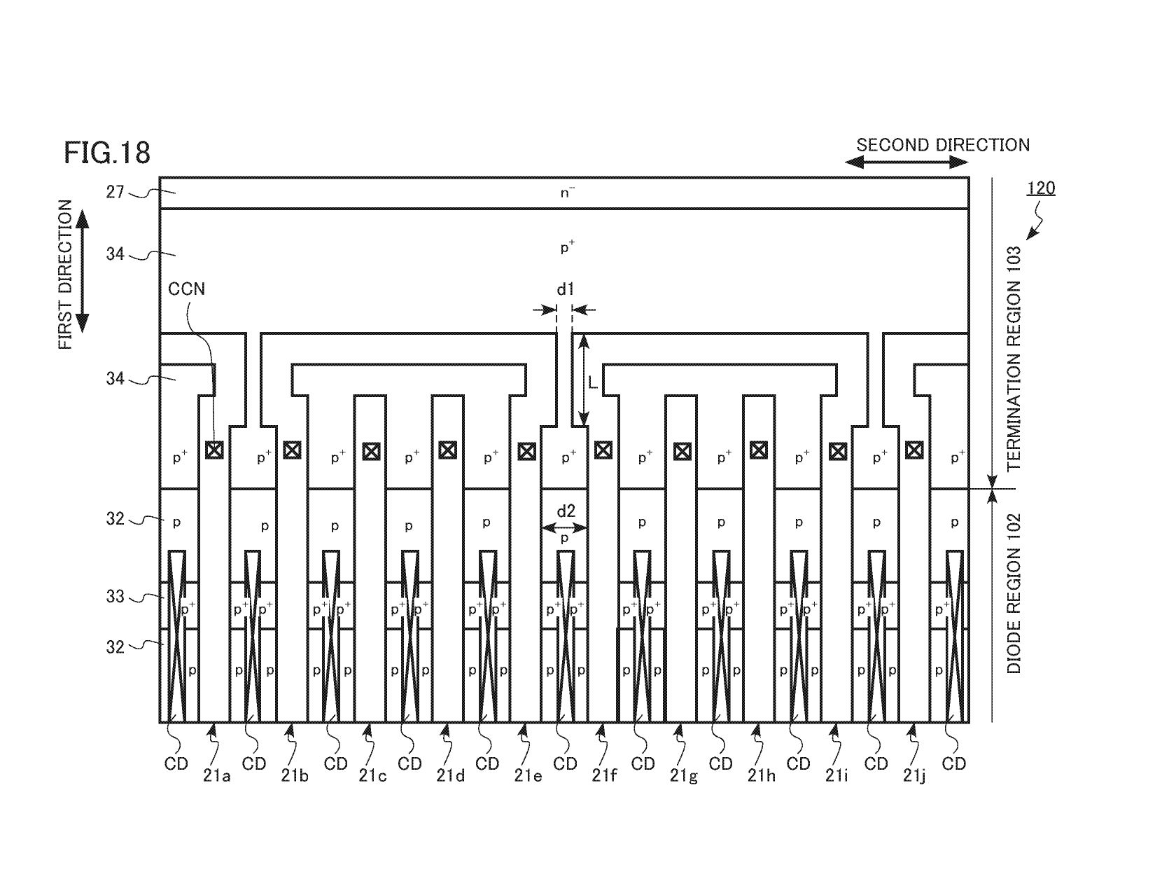

FIG. 18 is a schematic cross-sectional view of a part of the semiconductor device of the second modification of the first embodiment. FIG. 18 is a view corresponding to FIG. 7 of the first embodiment.

The B trench 21b is an example of the first trench. The E trench 21e is an example of the second trench. The F trench 21f is an example of the third trench. The I trench 21i is an example of the fourth trench. The C trench 21c is an example of the fifth trench. The G trench 21g is an example of the sixth trench. The D trench 21d is an example of the seventh trench. The H trench 21h is an example of the eighth trench.

The B trench 21b and the E trench 21e are physically connected in the termination region 103. The F trench 21f and the I trench 21i are physically connected in the termination region 103. The E trench 21e and the F trench 21f are adjacent to each other in the second direction.

The C trench 21c is provided between the B trench 21b and the E trench 21e. The G trench 21g is provided between the F trench 21f and the I trench 21i.

The D trench 21d is provided between the C trench 21c and the E trench 21e. The H trench 21h is provided between the G trench 21g and the I trench 21i.

A first minimum distance (d1 in FIG. 18) in the second direction between the E trench 21e and the F trench 21f in the termination region 103 is smaller than a second minimum distance (d2 in FIG. 18) in the second direction between the E trench 21e and the F trench 21f in the diode region 102.

For example, a length (L in FIG. 18) in the first direction of a portion where a distance in the second direction between the E trench 21e and the F trench 21f in the termination region 103 is equal to or less than the second minimum distance d2 is longer than the second minimum distance d2 and equal to or less than 100 times the second minimum distance d2.

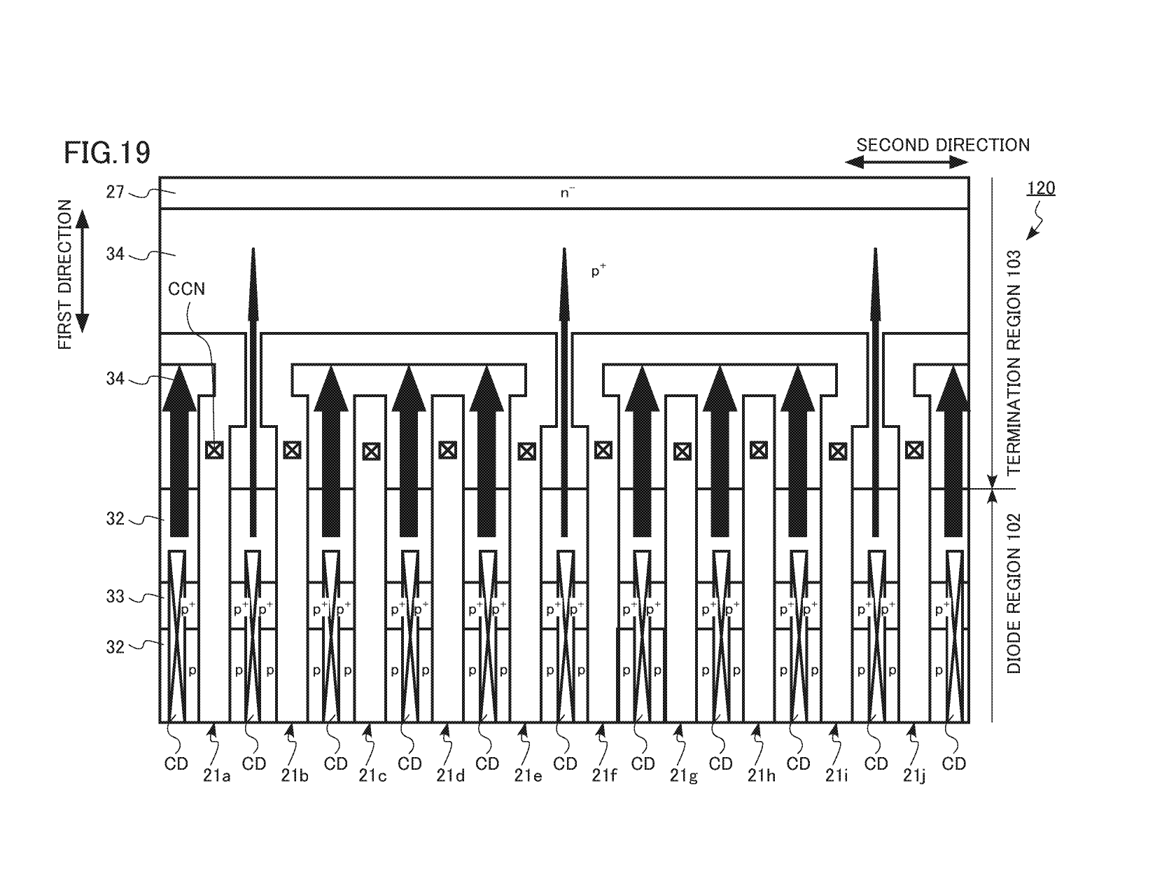

FIG. 19 is an explanatory diagram of the function and effect of the semiconductor device of the second modification of the first embodiment. FIG. 19 is a diagram illustrating a current flow when the diode of the diode region 102 of the RC-IGBT 120 of the second modification of the first embodiment is in a conducting state. FIG. 19 is a view corresponding to FIG. 13 of the first embodiment.

In FIG. 19, the current flow is indicated by an arrow.

As is clear from FIG. 19, when the diode is in a conducting state, the ratio of the current interrupted by the physically connected trenches 21 of the first group further increases in the current flowing from the anode region 32 toward the guard ring region 34. The number of paths passing between the two adjacent trenches 21 of the first group not physically connected also further decreases. Therefore, the current flowing from the anode region 32 toward the guard ring region 34 further decreases.

Therefore, holes injected into the drift region 27 from the guard ring region 34 are further reduced. Thus, the reverse recovery loss (Err) of the RC-IGBT 120 is further reduced.

According to the second modification of the first embodiment, as in the first embodiment, the reverse recovery loss (Err) of the RC-IGBT is reduced.

As described above, according to the first embodiment and the modifications, a semiconductor device including an RC-IGBT having an IGBT and a diode and capable of improving characteristics by reducing the reverse recovery loss (Err) can be realized.

### Second Embodiment

A semiconductor device of a second embodiment is different from the semiconductor device of the first embodiment in that the fourth semiconductor region includes a first region and a second region provided between the first region and the third semiconductor region and having a second conductivity type impurity concentration lower than a second conductivity type impurity concentration of the first region. Hereinafter, description of contents overlapping with the first embodiment may be partially omitted.

The semiconductor device of the second embodiment is an RC-IGBT 200 in which an IGBT and a free wheeling diode are formed on the same semiconductor chip.

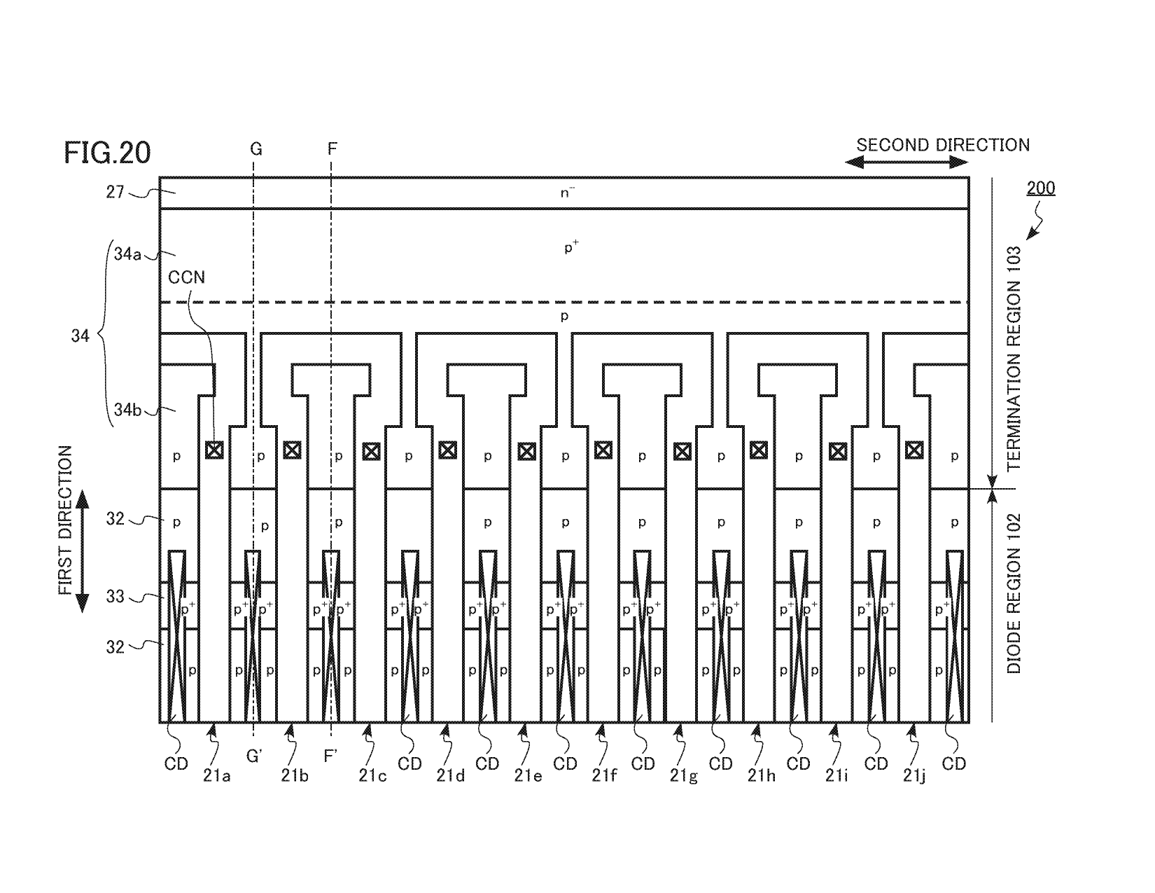

FIG. 20 is a schematic top view of a part of the semiconductor device of the second embodiment. FIG. 20 is a view corresponding to FIG. 7 of the first embodiment.

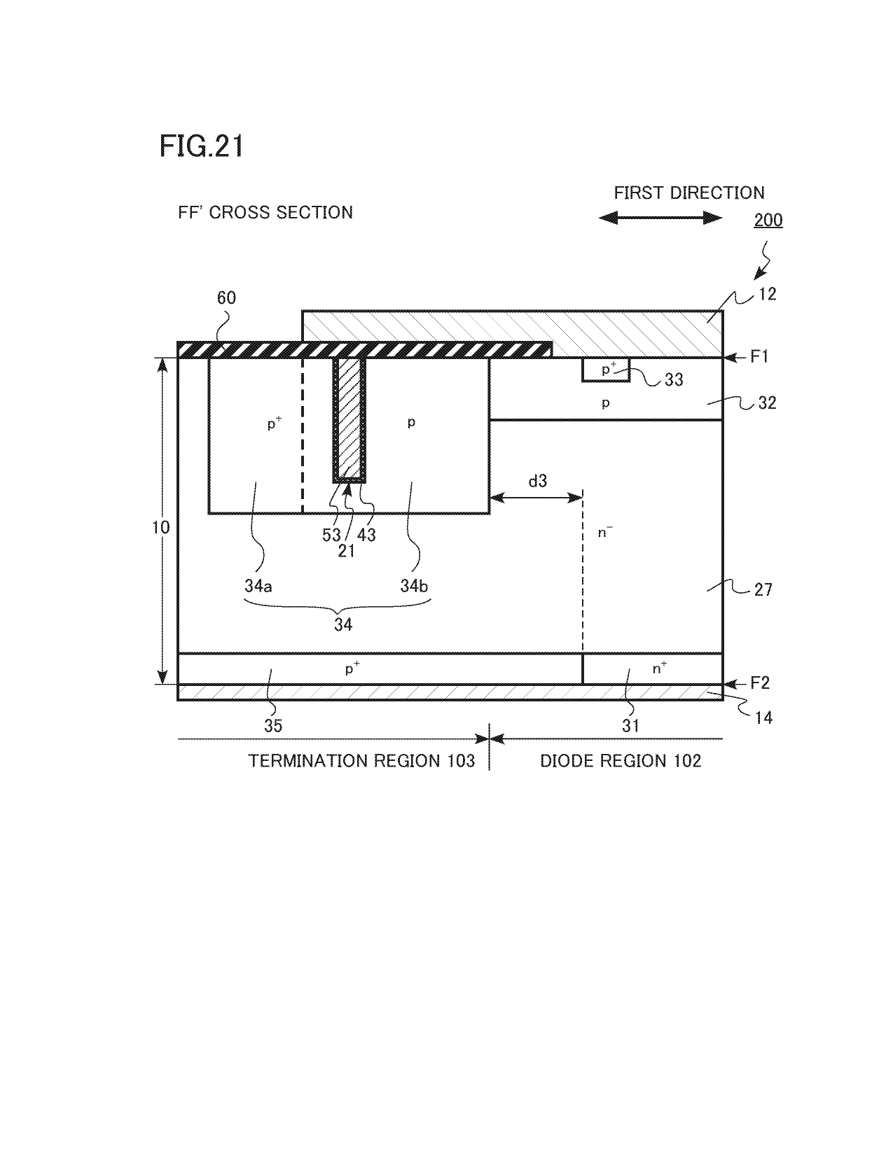

FIG. 21 is a schematic cross-sectional view of a part of the semiconductor device of the second embodiment. FIG. 21 is a schematic cross-sectional view including a boundary portion between the diode region and the termination region. FIG. 21 is an FF’ cross section of FIG. 20.

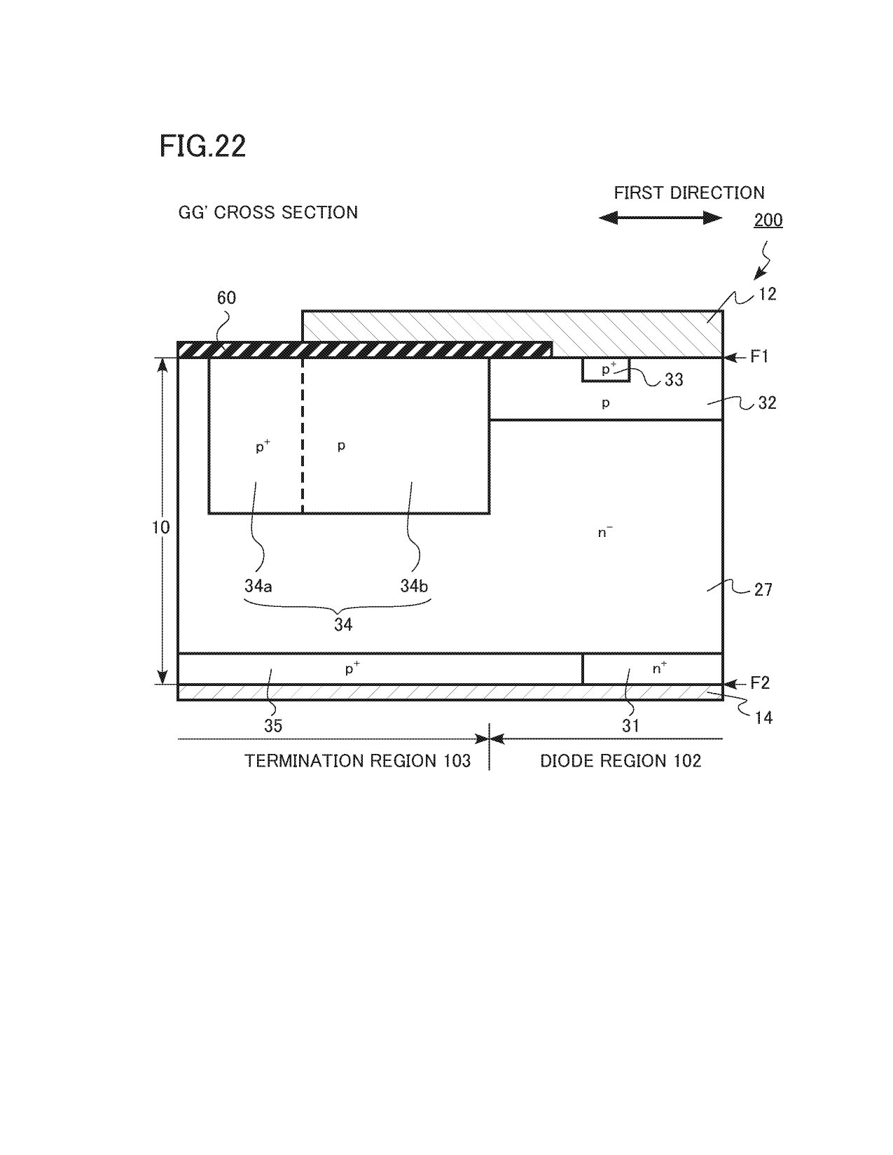

FIG. 22 is a schematic cross-sectional view of a part of the semiconductor device of the second embodiment. FIG. 22 is a schematic cross-sectional view including a boundary portion between the diode region and the termination region. FIG. 22 is a GG’ cross section of FIG. 20.

The guard ring region 34 (fourth semiconductor region) includes a high-concentration region 34a (first region) and a low-concentration region 34b (second region).

The low-concentration region 34b is provided between the high-concentration region 34a and the anode region 32 (third semiconductor region).

The p-type impurity concentration of the low-concentration region 34b is lower than the p-type impurity concentration of the high-concentration region 34a. The p-type impurity concentration of the low-concentration region 34b is, for example, equal to or more than 1/10 and equal to or less than 1/2 of the p-type impurity concentration of the high-concentration region 34a.

The p-type impurity concentration of the high-concentration region 34a is, for example, higher than the p-type impurity concentration of the anode region 32. The p-type impurity concentration of the low-concentration region 34b is, for example, higher than the p-type impurity concentration of the anode region 32.

In the RC-IGBT 200 of the second embodiment, by providing the low-concentration region 34b between the high-concentration region 34a and the anode region 32 (third semiconductor region), the electrical resistance of the path from the anode region 32 toward the guard ring region 34 increases when the diode is in a conducting state. Therefore, the current flowing from the anode region 32 toward the guard ring region 34 further decreases as compared with the RC-IGBT 100 of the first embodiment.

Therefore, holes injected into the drift region 27 from the guard ring region 34 are further reduced. Thus, the reverse recovery loss (Err) of the RC-IGBT 200 is further reduced.

The p-type impurity concentration of the low-concentration region 34b is preferably equal to or less than 1/2 and more preferably equal to or less than 1/5 of the p-type impurity concentration of the high-concentration region 34a. When the electrical resistance of the path from the anode region 32 toward the guard ring region 34 increases, the current flowing from the anode region 32 toward the guard ring region 34 further decreases.

As described above, according to the second embodiment, a semiconductor device including an RC-IGBT having an IGBT and a diode and capable of improving characteristics by reducing the reverse recovery loss (Err) can be realized.

In the first and second embodiments, a case where the semiconductor layer is single crystal silicon has been described as an example, but the semiconductor layer is not limited to single crystal silicon. For example, other single crystal semiconductors such as single crystal silicon carbide may be used.

In the first and second embodiments, a case where the first conductivity type is n-type and the second conductivity type is p-type has been described as an example, but the first conductivity type may be p-type and the second conductivity type may be n-type.

The layout pattern in the termination region of the trenches of the second group included in the transistor region is not necessarily limited to the pattern illustrated in FIG. 4 in the first embodiment. For example, it is possible to physically connect a part of the trenches of the second group in the termination region.

While certain embodiments have been described, these embodiments have been presented by way of example only, and are not intended to limit the scope of the inventions. Indeed, the semiconductor device described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A semiconductor device comprising:
a transistor region;
a diode region; and
a termination region surrounding the transistor region and the diode region, wherein
the diode region includes:
a semiconductor layer having a first face and a second face opposed to the first face;
a first semiconductor region of a first conductivity type provided in the semiconductor layer;
a second semiconductor region of the first conductivity type provided in the semiconductor layer, provided between the first semiconductor region and the first face, and having a first conductivity type impurity concentration lower than a first conductivity type impurity concentration of the first semiconductor region;
a third semiconductor region of a second conductivity type provided in the semiconductor layer and provided between the second semiconductor region and the first face;
trenches of a first group provided on a side of the first face of the semiconductor layer, extending in a first direction parallel to the first face, arranged repeatedly in a second direction parallel to the first face and perpendicular to the first direction, and in contact with the second semiconductor region and the third semiconductor region;
a first electrode electrically connected to the third semiconductor region; and
a second electrode in contact with the first semiconductor region,
the termination region includes:
the semiconductor layer;
the second semiconductor region;
a fourth semiconductor region of the second conductivity type provided in the semiconductor layer, provided between the second semiconductor region and the first face, electrically connected to the first electrode, and having a depth deeper than a depth of the third semiconductor region;
the trenches of the first group; and
the second electrode,
wherein the trenches of the first group include a first trench, a second trench, a third trench, and a fourth trench,
the first trench and the second trench are physically connected in the termination region,
the third trench and the fourth trench are physically connected in the termination region,
the second trench and the third trench are adjacent to each other in the second direction, and
a first minimum distance in the second direction between the second trench and the third trench in the termination region is smaller than a second minimum distance in the second direction between the second trench and the third trench in the diode region.

2. The semiconductor device according to claim 1, wherein the first minimum distance is equal to or less than 1/2 of the second minimum distance.

3. The semiconductor device according to claim 1, wherein the trenches of the first group further include a fifth trench and a sixth trench,
the fifth trench is provided between the first trench and the second trench, and
the sixth trench is provided between the third trench and the fourth trench.

4. The semiconductor device according to claim 3, wherein the trenches of the first group further include a seventh trench and an eighth trench,
the seventh trench is provided between the fifth trench and the second trench, and
the eighth trench is provided between the sixth trench and the fourth trench.

5. The semiconductor device according to claim 1, wherein a second conductivity type impurity concentration of the fourth semiconductor region is higher than a second conductivity type impurity concentration of the third semiconductor region.

6. The semiconductor device according to claim 1, wherein the fourth semiconductor region includes a first region and a second region provided between the first region and the third semiconductor region and having a second conductivity type impurity concentration lower than a second conductivity type impurity concentration of the first region.

7. The semiconductor device according to claim 1, wherein the semiconductor layer in the termination region further includes a fifth semiconductor region of the second conductivity type provided between the second semiconductor region and the second face and in contact with the second electrode.

8. The semiconductor device according to claim 7, wherein a boundary between the fifth semiconductor region and the first semiconductor region exists in the diode region, and a distance in the first direction between the fourth semiconductor region and the first semiconductor region is equal to or more than 100 μm.

9. The semiconductor device according to claim 1, wherein a length in the first direction of a portion where a distance in the second direction between the second trench and the third trench in the termination region is equal to or less than the second minimum distance is longer than the second minimum distance.

10. The semiconductor device according to claim 1, wherein the transistor region includes:
the semiconductor layer;
the second semiconductor region;
a sixth semiconductor region of the second conductivity type provided in the semiconductor layer and provided between the second semiconductor region and the second face;
a seventh semiconductor region of the second conductivity type provided in the semiconductor layer and provided between the second semiconductor region and the first face;
an eighth semiconductor region of the first conductivity type provided in the semiconductor layer and provided between the seventh semiconductor region and the first face;
trenches of a second group provided on a side of the first face in the semiconductor layer, extending in the first direction, arranged repeatedly with equal to or more than 10 trenches in the second direction, and in contact with the second semiconductor region, the seventh semiconductor region, and the eighth semiconductor region;
the first electrode in contact with the eighth semiconductor region; and
the second electrode in contact with the sixth semiconductor region,
wherein the termination region further includes the trenches of the second group,
a minimum distance in the second direction between any two adjacent trenches in the trenches of the second group is substantially the same in the termination region, and
the trenches of the second group are not physically connected to each other.
